(19) United States
(12) Patent Application Publication
(10) Pub. No.: US 2026/0214887 A1
(43) Pub. Date: Jul. 23, 2026

(54) SEMICONDUCTOR DEVICE

(71) Applicant: Samsung Electronics Co., Ltd., Suwon-si (KR)

(72) Inventors: Juho Lee, Suwon-si (KR); Seung Min Lee, Suwon-si (KR); Sungjin Kim, Suwon-si (KR); Hwayeong Lee, Suwon-si (KR); Sungduk Hong, Suwon-si (KR)

(73) Assignee: Samsung Electronics Co., Ltd., Suwon-si, (KR)

(21) Appl. No.: 19/349,031

(22) Filed: Oct. 3, 2025

(30) Foreign Application Priority Data
Apr. 18, 2025 (KR) 10-2025-0050620

(51) Int. Cl. H10B 12/00; H10D 1/68; H10D 30/67

(52) U.S. Cl. CPC H10B 12/482; H10B 12/03; H10B 12/05; H10B 12/485; H10B 12/488; H10D 30/6735; H10D 1/714

(57) ABSTRACT

Provided is a semiconductor device including a bit line extending in a first direction, semiconductor patterns spaced apart in the first direction and having one end in a second direction connected to the bit line, a word line extending in a third direction and positioned on one side of each of the semiconductor patterns in the first direction, and data storage patterns connected to another end of each of the semiconductor patterns in the second direction, wherein the bit line includes a core conductive layer, and a first oxide semiconductor layer positioned between the core conductive layer and the semiconductor patterns and connected to the semiconductor patterns.

### CROSS-REFERENCE TO RELATED APPLICATIONS

This present application claims priority to and the benefit under 35 U.S.C. § 119(a)-(d) of Korean Patent Application No. 10-2025-0050620, filed on Apr. 18, 2025, in the Korean Intellectual Property Office, the entire disclosure of which is incorporated herein by reference.

### FIELD

The present disclosure relates to a semiconductor device.

### BACKGROUND

A technique for increasing the integration degree of a semiconductor device is required. In the case of a two-dimensional semiconductor device, the integration degree is primarily determined by the area occupied by a unit memory cell, and this aspect of integration may be influenced by the level of fine pattern formation technology.

However, in the case of fine pattern formation technology, expensive equipment is required, so although the integration degree of two-dimensional semiconductor devices is increasing, it is still limited. Accordingly, three-dimensional semiconductor memory devices having memory cells arranged in three dimensions are being proposed.

### SUMMARY

Aspects of the present disclosure may provide a semiconductor device having low leakage current, capable of increasing integration density, and preventing the degradation of the semiconductor pattern, thereby enhancing operational reliability. The contact area between the bit line and the semiconductor pattern may increase, reducing the contact resistance between the semiconductor pattern and the bit line, which may improve operational characteristics.

Embodiments of the present disclosure provide a semiconductor device including a bit line extending in a first direction, semiconductor patterns spaced apart in the first direction and having one end in a second direction, different from the first direction, connected to the bit line, a word line extending in a third direction, different from the first and the second directions, and positioned on one side of each of the semiconductor patterns in the first direction, and data storage patterns connected to another end of each of the semiconductor patterns in the second direction, wherein the bit line includes a core conductive layer, and a first oxide semiconductor layer positioned between the core conductive layer and the semiconductor patterns and connected to the semiconductor patterns.

Embodiments of the present disclosure provide a semiconductor device including a bit line extending in a first direction, semiconductor patterns spaced apart in the first direction and having one end in a second direction, different from the first direction, connected to the bit line, a word line extending in a third direction, different from the first and second directions, and positioned on one side of each of the semiconductor patterns in the first direction, a gate insulating layer positioned between each of the semiconductor patterns and the word line, and including a gate insulating pattern layer positioned on a side of each of the semiconductor patterns and a gate insulating liner positioned on a side of the word line, and a data storage pattern connected to another end of each of the semiconductor patterns in the second direction, wherein the gate insulating liner has a first insulating liner portion positioned between the word line and the gate insulating pattern layer, and a second insulating liner portion positioned between the word line and the data storage patterns.

Embodiments of the present disclosure provide a semiconductor device including a bit line extending in a first direction, a semiconductor structure having one side in a second direction, different from the first direction, connected to the bit line, a word line extending in a third direction, different from the first and the second directions, and positioned on one side in the first direction of the semiconductor structure, and a data storage pattern connected to another side in the second direction of the semiconductor structure, wherein the semiconductor structure includes a first portions overlapping with the word line in the first direction, having the other side in the second direction connected to the data storage pattern, and spaced apart in the first direction, and a second portion extending in the first direction, connecting the first portions, and positioned between the bit line and the first portions.

Embodiments of the present disclosure provide a method of manufacturing a semiconductor device including forming a preliminary stack over a substrate by alternately stacking sacrificial patterns and preliminary semiconductor patterns, with gate insulating pattern layers interposed between the sacrificial patterns and the preliminary semiconductor patterns, forming a first electrode on one side of the preliminary semiconductor patterns, forming a dielectric layer on the first electrode, forming a second electrode on the dielectric layer to form a data storage pattern, removing another side of the sacrificial patterns to expose the gate insulating pattern layers and forming a gate insulating liner on the gate insulating pattern layers to form a gate insulating layer, forming a word line on the gate insulating liner, removing the preliminary semiconductor patterns and simultaneously forming semiconductor patterns and a first oxide semiconductor layer, and forming a bit line by forming a core conductive layer on the first oxide semiconductor layer.

The semiconductor patterns may be formed in the space where the preliminary semiconductor patterns are removed, and the first oxide semiconductor layer may be formed on one side of the gate insulating pattern layers and the gate insulating liner, and the first oxide semiconductor layer and the semiconductor patterns may be simultaneously formed in one process.

When forming the first oxide semiconductor layer connected to the semiconductor patterns while forming the semiconductor patterns, a concave portion may be formed on a side of the first oxide semiconductor layer facing the core conductive layer, and the concave portion may be indented with respect to the semiconductor pattern.

Forming the bit line may include forming a second oxide semiconductor layer on the first oxide semiconductor layer, and forming the core conductive layer on the second oxide semiconductor layer.

Forming the preliminary stack may include alternately stacking sacrificial layers and active layers on the substrate, with gate insulating pattern material layers interposed between the sacrificial layers and active layers, patterning the sacrificial layers, the active layers, and the gate insulating pattern material layers to form first trenches extending in a second direction substantially parallel to the upper surface of the substrate and spaced apart in a third direction different from the second direction, configuring the remaining sacrificial layers as first sacrificial patterns and the remaining active layers as first preliminary semiconductor patterns, forming first preliminary filling patterns filling the first trenches, patterning the first sacrificial patterns, the first preliminary semiconductor patterns, and the gate insulating pattern material layers to form second trenches extending in the third direction and spaced apart in the second direction, configuring the remaining first preliminary semiconductor patterns as second preliminary semiconductor patterns and the remaining gate insulating pattern material layers as a gate insulating pattern layer, and forming second preliminary filling patterns filling the second trenches.

Forming the data storage pattern may include removing some of the second preliminary filling patterns to re-expose some of the second trenches, removing one side in the second direction of the first sacrificial patterns exposed by the second trenches, configuring the remaining first sacrificial patterns as second sacrificial patterns, forming a first sacrificial insulation pattern in the space where the first sacrificial patterns are removed, forming a second sacrificial insulation pattern on the first sacrificial insulation pattern to fill the space where the first sacrificial patterns are removed, forming a third sacrificial insulation pattern on the first and second sacrificial insulation patterns to form a sacrificial insulation structure, removing one side in the second direction of the first preliminary semiconductor patterns and the gate insulation pattern layers, configuring the remaining first preliminary semiconductor patterns as second preliminary semiconductor patterns, forming a first electrode in the space where the first preliminary semiconductor patterns and the gate insulation pattern layers are removed, removing the sacrificial insulation structure, forming a dielectric layer on the first electrode, and forming a second electrode on the dielectric layer and in the space where the sacrificial insulation structure is removed.

Forming the gate insulating layer may include exposing the gate insulating pattern layers by removing the second sacrificial patterns at one side in the second direction, forming a gate insulating liner material layer on the gate insulating pattern layers, forming a capping material layer on the gate insulating liner material layer, forming a word line separation material layer on the capping material layer, forming a word line separation layer by removing a portion of the word line separation material layer formed on the other side in the second direction of the second preliminary semiconductor patterns and the gate insulating pattern layers, forming a capping pattern by exposing one end of the capping material layer in the second direction and removing part from one end of the capping material layer in the second direction, and forming a gate insulating liner by removing a portion of the gate insulating liner material layer formed on one side in the second direction of the preliminary semiconductor patterns and the gate insulating pattern layers.

Forming the word line may include forming a preliminary gate conductive layer in the space where the capping material layer is removed, removing a portion of the preliminary gate conductive layer formed on another side in the second direction of the second preliminary semiconductor patterns and the gate insulating pattern layers to form the word line, recessing the other end in the second direction of the word line when removing a portion of the preliminary gate conductive layer to form a first spacer in the space where the word line is recessed.

The semiconductor device according to embodiments may have a semiconductor pattern including an oxide semiconductor material, which may have low leakage current and may increase integration density.

The gate insulating layer may prevent hydrogen from penetrating into the semiconductor pattern by including a gate insulating pattern layer and a gate insulating liner, thereby preventing the semiconductor pattern from deteriorating and improving operational reliability.

The bit line, including a first oxide semiconductor layer connected to the semiconductor pattern, may enhance the operational characteristics by increasing the contact area between the bit line and the semiconductor pattern, thus reducing the contact resistance between the semiconductor pattern and the bit line.

The method of manufacturing a semiconductor device according to other embodiments may form the main components by a deposition process rather than an epitaxial growth process, thereby potentially facilitating the manufacturing process of the semiconductor device.

By first forming the data storage pattern, then forming the word lines, and subsequently replacing the preliminary semiconductor patterns with the semiconductor patterns before forming the bit lines, it is possible to minimize chemical and thermal damage to the semiconductor patterns including an oxide semiconductor material and to improve the characteristics of the semiconductor patterns.

Because the first oxide semiconductor layer of the bit line connected with semiconductor patterns is formed together while forming the semiconductor patterns, it may eliminate disconnection defects between the semiconductor patterns and the bit line.

### BRIEF DESCRIPTION OF THE DRAWINGS

FIG. 1 is a perspective view showing a semiconductor device according to embodiments.

FIG. 2 is a cross-sectional view taken along line A-A′ of FIG. 1.

FIG. 3 is a cross-sectional view taken along the B-B′ line and C-C′ line of FIG. 1.

FIG. 4 is a cross-sectional view taken along line D-D′ of FIG. 1.

FIG. 5 is a cross-sectional view enlarging the P portion of FIG. 2.

FIG. 6 is a cross-sectional view taken along line A-A′ of FIG. 1, corresponding to FIG. 2.

FIG. 7 is a cross-sectional view enlarging the Q portion of FIG. 6.

FIG. 8 is a cross-sectional view taken along line A-A′ of FIG. 1, corresponding to FIG. 2.

FIG. 9 is a cross-sectional view taken along line D-D′ of FIG. 1, corresponding to FIG. 4.

FIG. 10 is a cross-sectional view taken along line A-A′ of FIG. 1, corresponding to FIG. 2.

FIG. 11 is a cross-sectional view taken along line A-A′ of FIG. 1, corresponding to FIG. 2.

FIGS. 12 to 67 are cross-sectional views showing a method of manufacturing a semiconductor device according embodiments in process order.

### DETAILED DESCRIPTION

Hereinafter, various embodiments of the present disclosure will be described in detail with reference to the attached drawings so that a person having ordinary skill in the art to which the present disclosure pertains can easily implement the present disclosure. The present disclosure may be embodied in many different forms and is not limited to the embodiments set forth herein.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

Additionally, throughout the specification, the direction vertical to the upper surface of the substrate is described as a first direction D1, and the two directions that are parallel to the upper surface of the substrate and intersect each other are described as a second direction D2 and a third direction D3 respectively. For example, the second direction D2 and the third direction D3 may be perpendicular to each other.

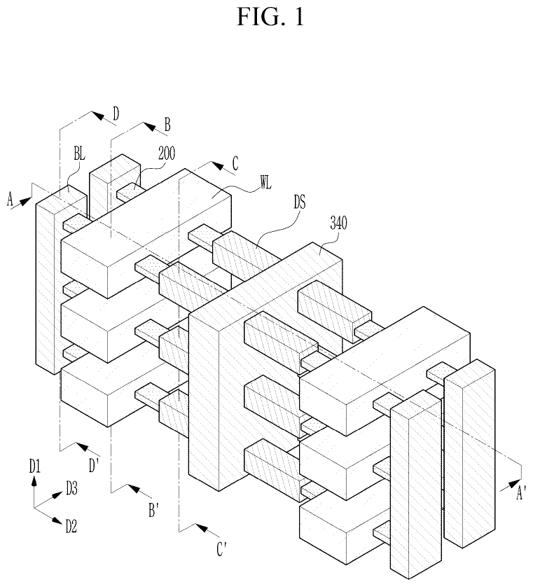

Hereinafter, referring to FIGS. 1 to 5, a semiconductor device according to embodiments will be described.

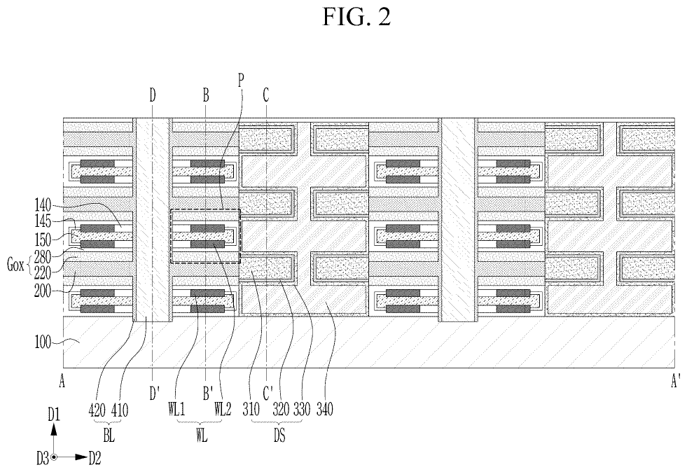

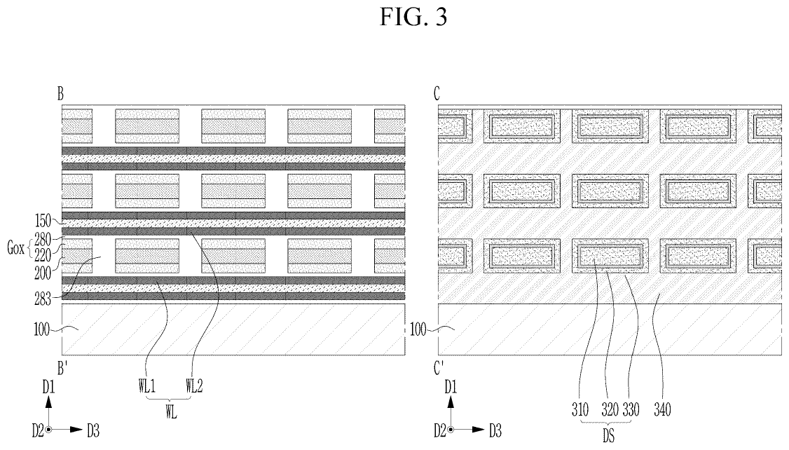

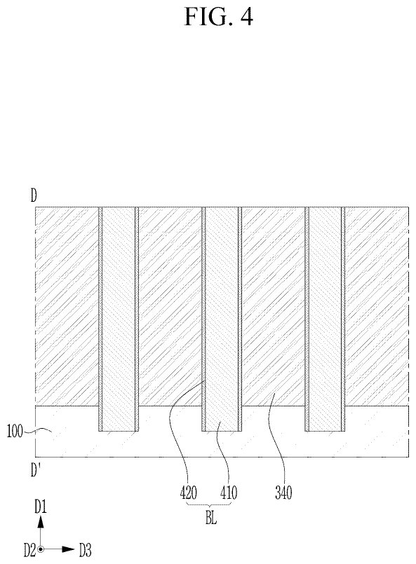

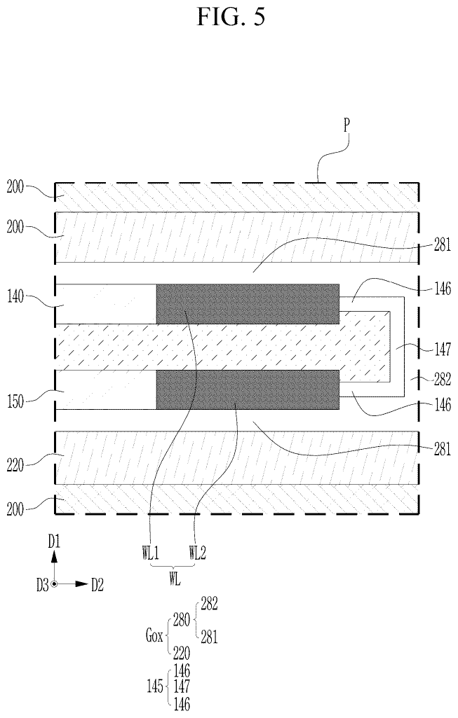

FIG. 1 is a perspective view showing a semiconductor device according to embodiments. FIG. 2 is a cross-sectional view taken along line A-A′ of FIG. 1. FIG. 3 is a cross-sectional view taken along lines B-B′ and C-C′ of FIG. 1. FIG. 4 is a cross-sectional view taken along line D-D′ of FIG. 1. FIG. 5 is a cross-sectional view enlarging the P portion of FIG. 2.

FIG. 1 to FIG. 5, the semiconductor device may include memory cells arranged in three dimensions. The memory cells may be arranged in a first direction D1, a second direction D2, and a third direction D3.

For example, the memory cells may be stacked in a first direction D1. FIGS. 1 to 5 show memory cells that are commonly connected to a bit line BL and stacked in three layers in the first direction D1, but are not limited thereto, as the memory cells may be stacked in more layers.

In addition, the memory cells of each layer may be spaced apart in a second direction D2 and a third direction D3. For example, the memory cells may be arranged in a mirror-symmetrical form in the second direction D2. One memory cell and its mirror-symmetrical memory cell may constitute a pair, and pairs of memory cells may share a second electrode 330 of the data storage pattern DS, which will be described later.

The memory cell may be connected to a bit line BL and a word line WL. The bit line BL may extend along a first direction D1. A single bit line BL may commonly connect memory cells stacked in the first direction D1. A bit lines BL may be spaced apart and arranged along a third direction D3. The word line WL may extend along the third direction D3. A single word line WL may commonly connect memory cells arranged along the third direction D3. A word lines WL may be spaced apart and arranged along the first direction D1.

For example, the memory cells may be positioned on the substrate 100. The substrate 100 may be, for example, a silicon substrate, a germanium substrate, a silicon-germanium substrate, an insulator substrate, a silicon-on-insulator (SOI) substrate, or a germanium-on-insulator (GOI) substrate.

In some embodiments, a peripheral circuit for operating memory cells may be positioned on the substrate 100. Also, wiring electrically connected to the bit lines BL and word lines WL may be positioned over the memory cells, and the wiring may be connected to the peripheral circuit.

The bit lines BL may be spaced apart from each other in the second direction D2 and the third direction D3, and may extend in the first direction D1. For example, the bit line BL may have a line shape or a column shape extending in the first direction D1.

The bit line BL may have both sides in the second direction D2 connected to the semiconductor patterns 200, which are spaced apart along the first direction D1 and positioned on both sides in the second direction D2 of the bit line BL. The bit line BL may be electrically connected to the semiconductor patterns 200.

For example, the bit line BL may include a core conductive layer 410 and a first oxide semiconductor layer 420.

The core conductive layer 410 may extend in the first direction D1. For example, the core conductive layer 410 may have a line shape or column shape extending in the first direction D1. Additionally, the shape of the core conductive layer 410 in a plane may be circular, but is not limited thereto. For example, the shape of the core conductive layer 410 in a plane may be a quadrangle, a polygon having five or more angles, or an ellipse.

The core conductive layer 410 may include a conductive material. The conductive material may include, for example, a doped semiconductor material such as doped silicon or doped germanium, a conductive metal nitride such as titanium nitride or tantalum nitride, a metal such as tungsten, titanium, or tantalum, a metal-semiconductor compound such as tungsten silicide, cobalt silicide, or titanium silicide, or a combination thereof. For example, the core conductive layer 410 may include a core layer extending in a first direction D1 from the center and a barrier layer extending in the first direction D1 on the outer sidewall of the core layer. For example, the barrier layer may be interposed between the core layer and the first oxide semiconductor layer 420. For example, the core layer may include tungsten, and the barrier layer may include titanium and titanium nitride.

The first oxide semiconductor layer 420 may be positioned between the core conductive layer 410 and the semiconductor pattern 200. The first oxide semiconductor layer 420 may extend in a first direction D1 along the core conductive layer 410. The first oxide semiconductor layer 420 may conformally cover the side surfaces of the core conductive layer 410. In other words, the first oxide semiconductor layer 420 may be a thin film having a uniform thickness following the side surface shape of the core conductive layer 410.

For example, the first oxide semiconductor layer 420 may cover all the sides of the core conductive layer 410. For example, the first oxide semiconductor layer 420 may have a ring shape surrounding the core conductive layer 410, continuously extending in a plane. Furthermore, corresponding to the planar shape of the core conductive layer 410, the planar shape of the first oxide semiconductor layer 420 may be a quadrilateral ring, a polygonal ring having five or more angles, a circular ring, or an elliptical ring.

The first oxide semiconductor layer 420 may conformally cover one side in the second direction D2 of the semiconductor patterns 200, the gate insulating pattern layers 220 to be described later, the gate insulating liners 280, the first spacers 140, and the word line separation layers 150.

The first oxide semiconductor layer 420 may be connected to one side in the second direction D2 of the semiconductor patterns 200. For example, the first oxide semiconductor layer 420 and the semiconductor pattern 200 may constitute a single body. In other words, the first oxide semiconductor layer 420 and the semiconductor pattern 200 may be combined to form an integral unit.

As described below, when replacing the preliminary semiconductor patterns 170 with the semiconductor patterns 200, the first oxide semiconductor layer 420 of the bit line BL connected to the semiconductor patterns 200 may be formed together. As the first oxide semiconductor layer 420 of the bit line BL and the semiconductor patterns 200 are simultaneously formed in one process, the first oxide semiconductor layer 420 and the semiconductor patterns 200 may constitute a single body. In other words, the first oxide semiconductor layer 420 and the semiconductor patterns 200 may include an oxide semiconductor material having the same composition, and their boundary may not be distinguishable.

Thus, it may eliminate disconnection defects between the semiconductor patterns 200 and the bit line BL. In addition, the contact area between the bit line BL and the semiconductor patterns 200 may increase, reducing the contact resistance between the semiconductor patterns 200 and the bit line BL, which may improve the operational characteristics of the semiconductor device.

The first oxide semiconductor layer 420 may include the same oxide semiconductor material as the semiconductor patterns 200. The oxide semiconductor material may be a combination of at least two of In, Ga, Zn, Al, Sn, and Hf, but is not limited thereto. The oxide semiconductor material may further include a material such as Si, Mg, Ta, La, Nd, Ce, Sc, Cr, Co, Nb, Mo, Ba, Gd, Ti, W, Pd, Ru, Ni, or Mn in the composition. For example, the first oxide semiconductor layer 420 may include IGZO (indium gallium zinc oxide), Sn-IGZO (tin-doped indium gallium zinc oxide), ITZO (indium tin zinc oxide), IZO (indium zinc oxide), ZnO (zinc oxide), ZTO (zinc tin oxide), ZnON (zinc oxynitride), ZZTO (zirconium zinc tin oxide), SnO (tin oxide), HIZO (hafnium indium zinc oxide), GZTO (gallium zinc tin oxide), AZTO (aluminium zinc tin oxide), YGZO (ytterbium gallium zinc oxide), IGO (indium gallium oxide), IWO (indium tungsten oxide), YZO (yttrium zinc oxide), or combinations thereof.

Bit line spacers 300 may be positioned spaced apart in the third direction D3 between bit lines BL. The bit line spacer 300 may include an insulating material and may space apart and insulate the bit lines BL from each other in the third direction D3. For example, the bit line spacer 300 may include a silicon nitride layer, a silicon oxynitride layer, a carbon-containing silicon oxide layer, a carbon-containing silicon nitride layer, a carbon-containing silicon oxynitride layer, or a combination thereof.

In some embodiments, bit line shield structures may be positioned spaced apart in a third direction D3 between bit lines BL. The bit lines BL and bit line shield structures may be spaced apart from each other along the third direction D3 and may be alternately positioned. For example, on each side of the bit line BL in the third direction D3, a bit line shield structure may be positioned. The bit line spacer 300 may be positioned between the bit line BL and the bit line shield structure.

The word line WL may extend along the third direction D3. The word line WL may have a line shape extending in the third direction D3. The word line WL may include a first word line WL1 passing below the semiconductor pattern 200 in the first direction D1 and a second word line WL2 passing above the semiconductor pattern 200 in the first direction D1. In other words, the first word line WL1 and the second word line WL2 may be spaced apart in the first direction D1 with the semiconductor pattern 200 interposed therebetween.

Each of the memory cells may include a first word line WL1, a semiconductor pattern 200, and a second word line WL2, and as the memory cells are stacked in a first direction D1, the first word line WL1 of one semiconductor pattern 200 and the second word line WL2 of the other semiconductor pattern 200 positioned below the first direction D1 of the one semiconductor pattern 200 may be adjacent. In this case, the first word line WL1 of one semiconductor pattern 200 and the second word line WL2 of the other semiconductor pattern 200 may be spaced apart in the first direction D1, and a word line separation layer 150 to be described later may be positioned between the first word line WL1 of one semiconductor pattern 200 and the second word line WL2 of the other semiconductor pattern 200.

In some embodiments, the word line WL may extend along a third direction D3, and in regions where it does not pass through the semiconductor pattern 200, the first word line WL1 and the second word line WL2 may be combined. In this case, the word line WL may surround the semiconductor pattern 200 or a stack including the semiconductor pattern 200 and a gate insulating pattern layer 220 to be described later.

The word line WL may include a conductive material. For example, the conductive material may include a semiconductor material, a conductive metal nitride, a metal, a metal-semiconductor compound, or combinations thereof.

A first spacer 140 may be positioned between the word line WL and the bit line BL. One end of the first spacer 140 in the second direction D2 may be connected to the bit line BL, and the other end of the first spacer 140 in the second direction D2 may be connected to the word line WL.

The first spacer 140 may include an insulating material and may space apart the bit line BL and the word line WL in a second direction D2, and insulate them from each other. For example, the first spacer 140 may include a silicon nitride layer, a silicon oxynitride layer, a carbon-containing silicon oxide layer, a carbon-containing silicon nitride layer, a carbon-containing silicon oxynitride layer, or a combination thereof.

A gate insulating layer Gox may be positioned between the word line WL and the semiconductor pattern 200. The gate insulating layer Gox may also be positioned between the first spacer 140 and the semiconductor pattern 200. The gate insulating layer Gox may also be positioned between a capping pattern 145 described below and the semiconductor pattern 200.

In some embodiments, the gate insulating layer Gox may surround a word line WL and a first spacer 140. The gate insulating layer Gox may cover the upper side, side, and lower side of the word line WL. The gate insulating layer Gox may cover the upper side and lower side of the first spacer 140.

The gate insulating layer Gox may include a high-k layer, a silicon oxide layer, a silicon nitride layer, a silicon oxynitride layer, or a combination thereof. The high-k layer may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

The gate insulating layer Gox may include a gate insulating pattern layer 220 and a gate insulating liner 280.

The gate insulating pattern layer 220 is positioned toward the semiconductor pattern 200 in the first direction D1, and the gate insulating liner 280 may be positioned toward the word line WL in the first direction D1.

The gate insulating pattern layer 220 may be positioned on one side or both sides of the semiconductor pattern 200 in the first direction D1. For example, the gate insulating layer Gox may include the gate insulating pattern layers 220, where one gate insulating pattern layer 220 is positioned on one side in the first direction D1 of the semiconductor pattern 200, and the other gate insulating pattern layer 220 may be positioned on the other side in the first direction D1 of the semiconductor pattern 200.

The gate insulating pattern layer 220 may extend in the second direction D2. One end of the gate insulating pattern layer 220 in the second direction D2 may be connected to the bit line BL. The other end of the gate insulating pattern layer 220 in the second direction D2 may be connected to the data storage pattern DS.

The length of the gate insulating pattern layers 220 in the third direction D3 may be equal to or greater than the length of the semiconductor patterns 200 in the third directions D3, and may be substantially the same. In this case, the semiconductor pattern 200 may be interposed between two gate insulating pattern layers 220 which are spaced apart in the first direction D1, and the upper and lower surfaces of the semiconductor pattern 200 may be covered by the gate insulating pattern layers 220. At this time, both sides of the semiconductor pattern 200 in the third direction D3 may be exposed, and the exposed sides of the semiconductor pattern 200 in the third direction D3 may be covered by the gate insulating liner 280.

In some embodiments, the gate insulating pattern layer 220 may be positioned only on the upper surface or the lower surface of the semiconductor pattern 200. In this case, the upper surface or lower surface of the semiconductor pattern 200 that is not covered by the gate insulating pattern layer 220 may be covered by the gate insulating liner 280.

The gate insulating liner 280 may be positioned on one side or both sides in the first direction D1 and on both sides in the third direction D3 of the semiconductor pattern 200. Alternatively, the gate insulating liner 280 may be positioned on one side in the first direction D1 and on both sides in the third direction D3 of the gate insulating pattern layer 220. In other words, if the gate insulating layer Gox does not include the gate insulating pattern layer 220, the gate insulating liner 280 may cover the upper surface and lower surface of the semiconductor pattern 200, and if the gate insulating pattern layer 220 is positioned only on the upper surface or lower surface of the semiconductor pattern 200, the gate insulating liner 280 may cover the upper surface or lower surface of the semiconductor pattern 200 and cover the upper surface or lower surface of the gate insulating pattern layer 220, and if the gate insulating pattern layer 220 is positioned on the upper surface and lower surface of the semiconductor pattern 200, the gate insulating liner 280 may cover the upper surface and lower surface of the gate insulating pattern layer 220. In any case, the gate insulating liner 280 may be positioned on both sides in the third direction D3 of the semiconductor pattern 200 and the gate insulating pattern layer 220. In other words, the gate insulating liner 280 may surround the semiconductor pattern 200, or a stack including the semiconductor pattern 200 and the gate insulating pattern layer 220.

The gate insulating liner 280 may have a first insulating liner portion 281 and a second insulating liner portion 282.

The first insulating liner portion 281 may extend in a second direction D2. One end of the first insulating liner portion 281 in the second direction D2 may be connected to the bit line BL. The other end of the first insulating liner portion 281 in the second direction D2 may be connected to the data storage pattern DS.

The first insulating liner portion 281 may be positioned between the word line WL and the gate insulating pattern layer 220 in the first direction D1. The first insulating liner portion 281 may be positioned between the first spacer 140 and the gate insulating pattern layer 220 in the first direction D1. The first insulating liner portion 281 may be positioned between the capping pattern 145 and the gate insulating pattern layer 220 in the first direction D1.

The first insulating liner portion 281 may be positioned between the first word line WL1 and the gate insulating pattern layer 220 in the first direction D1, and may be positioned between the second word line WL2 and the gate insulating pattern layer 220. The first insulating liner portion 281 may be positioned on both sides of the second insulating liner portion 282 in the first direction D1. In other words, the first insulating liner portion 281 positioned between the first word line WL1 and the gate insulating pattern layer 220 and the first insulating liner portion 281 positioned between the second word line WL2 and the gate insulating pattern layer 220 may be connected to both sides of one second insulating liner portion 282.

The first insulating liner portion 281 may extend long in the third direction D3 along the word line WL. The first insulating liner portion 281 may extend in the third direction D3 and may pass through the semiconductor patterns 200 and the gate insulating pattern layers 220 that are spaced apart in the third direction D3.

The second insulating liner portion 282 may extend in the first direction D1.

The second insulating liner portion 282 may be positioned in a second direction D2 between the word line WL and the data storage pattern DS. The second insulating liner portion 282 may be positioned in a second direction D2 between the word line separation layer 150 and the data storage pattern DS. The second insulating liner portion 282 may be positioned in a second direction D2 between the capping pattern 145 and the data storage pattern DS.

The second insulating liner portion 282 may extend long along the word line WL in the third direction D3.

For example, a length in the first direction D1 of the gate insulating pattern layer 220 may be greater than a length in the first direction D1 of the first insulating liner portion 281 of the gate insulating liner 280. In other words, the thickness of the gate insulating pattern layer 220 may be greater than the thickness of the first insulating liner portion 281.

In some embodiments, the gate insulating liner 280 may further have third insulating liner portions 283. The third insulating liner portions 283 may be positioned between the semiconductor patterns 200 spaced apart in the third direction D3. The third insulating liner portions 283 may extend in the first direction D1 and connect with the first insulating liner portions 281.

The first insulating liner portion 281 may be positioned on one side in the first direction D1 of the gate insulating pattern layer 220. The third insulating liner portions 283 may be positioned on both sides in the third direction D3 of the semiconductor pattern 200. Additionally, the third insulating liner portions 283 may be positioned on both sides in the third direction D3 of the gate insulating pattern layer 220. For example, the first insulating liner portions 281 and the third insulating liner portions 283 may surround the semiconductor pattern 200, or a stack including the semiconductor pattern 200 and the gate insulating pattern layer 220.

The gate insulating layer Gox, by including the gate insulating pattern layer 220 and the gate insulating liner 280, may block hydrogen from penetrating into the semiconductor pattern 200, thereby preventing the semiconductor pattern 200 from degrading, which may enhance operational reliability.

The memory cells may include layers, and word line separation layers 150 may be positioned between any two adjacent layers of the memory cells. In other words, the memory cells include the first word line WL1, the semiconductor pattern 200, and the second word line WL2. As the memory cells are stacked in the first direction D1, the first word line WL1 of one semiconductor pattern 200 and the second word line WL2 of the other semiconductor pattern positioned below the semiconductor pattern 200 in the first direction D1 may be adjacent. In this case, the first word line WL1 of one semiconductor pattern 200 and the second word line WL2 of the other semiconductor pattern may be spaced apart in the first direction D1, and the word line separation layer 150 may be positioned between the first word line WL1 of one semiconductor pattern 200 and the second word line WL2 of the other semiconductor pattern.

The word line separation layer 150 may extend in the third direction D3 along the word line WL.

One end of the word line separation layer 150 in the second direction D2 may connect to the bit line BL. The other end of the word line separation layer 150 in the second direction D2 may connect to the capping pattern 145.

The word line separation layer 150 may include an insulating material, for example, it may include a silicon nitride layer, a silicon oxynitride layer, a carbon-containing silicon oxide layer, a carbon-containing silicon nitride layer, or a carbon-containing silicon oxynitride layer.

In some embodiments, the word line separation layer 150 may include separation liners and a separation filling layer positioned between the separation liners. The separation liner may conformally cover one side in the first direction D1 of the first word line WL1 and the second word line WL2 positioned between the memory cells of each layer, and the separation filling layer may fill the space between the separation liners. The separation liner and the separation filling layer may each include an insulating material.

The capping pattern 145 may be positioned on one or both sides of the semiconductor pattern 200 in the first direction D1. The capping pattern 145 may be positioned on one or both sides of the gate insulating layer 220 in the first direction D1. The capping pattern 145 may contact the gate insulating liner 280 in the first direction D1.

The capping pattern 145 may be positioned between the word line WL and the data storage pattern DS in the second direction D2. The capping pattern 145 may be positioned between the word line separation layer 150 and the data storage pattern DS in the second direction D2.

The capping pattern 145 may extend long in the third direction D3 along the word line WL. The capping pattern 145 may extend long in the third direction D3 along the word line isolation layer 150.

For example, the capping pattern 145 may have a first capping portion 146 and a second capping portion 147.

The first capping portion 146 may be positioned between the word line separation layer 150 and the first insulating liner portion 281 of the gate insulating liner 280 in the first direction D1.

The first capping portion 146 may extend in the second direction D2. The first capping portion 146 may be positioned in the second direction D2 between the word line WL and the data storage pattern DS. The first capping portion 146 may be positioned in the second direction D2 between the word line WL and the second insulating liner portion 282 of the gate insulating liner 280.

The first capping portion 146 may be positioned at one end in the second direction D2 of the first word line WL1, which is positioned below the first direction D1 of one semiconductor pattern 200. Additionally, the first capping portion 146 may be positioned at one end in the second direction D2 of the second word line WL2, which is positioned above the first direction D1 of the other semiconductor pattern 200 positioned below the first direction D1 of the semiconductor pattern 200. In other words, the first capping portion 146 may be positioned in the second direction D2 between the first word line WL1 of one semiconductor pattern 200 and the second insulating liner portion 282, and the first capping portion 146 may be positioned in the second direction D2 between the second word line WL2 of the other semiconductor pattern 200 and the second insulating liner portion 282.

For example, a length in the first direction D1 of the word line WL may be greater than a length in the first direction D1 of the first capping portion 146. In other words, the thickness of the word line WL may be greater than the thickness of the first capping portion 146.

Accordingly, the length of the first direction D1 of the word line separation layer 150 may vary depending on the position in the second direction D2. For example, the length in the first direction D1 of the word line separation layer 150 positioned between the first word line WL1 and the second word line WL2 may be smaller than the length in the first direction D1 of the word line separation layer 150 positioned between the first capping portion 146 positioned at one end in the second direction D2 of the first word line WL1 and the first capping portion 146 positioned at one end in the second direction D2 of the second word line WL2.

The second capping portion 147 may extend in the first direction D1. The second capping portion 147 may be positioned between the word line separation layer 150 and the data storage pattern DS in the second direction D2. The second capping portion 147 may be positioned between the word line separation layer 150 and the second insulating liner portion 282 of the gate insulating liner 280 in the second direction D2. In other words, one side in the second direction D2 of the second capping portion 147 may contact the word line separation layer 150. The other side in the second direction D2 of the second capping portion 147 may contact the second insulating liner portion 282.

The first capping portion 146 may be positioned on both sides of the second capping portion 147 in the first direction D1. In other words, the second capping portion 147 may connect the first capping portion 146 positioned at one end of the first word line WL1 in the second direction D2 of one semiconductor pattern 200 and the first capping portion 146 positioned at one end of the second word line WL2 in the second direction D2 of the other semiconductor pattern 200.

The capping pattern 145 may include an insulating material. The capping pattern 145 may, for example, include a silicon oxide layer, a silicon oxynitride layer, a silicon nitride layer, or a combination thereof.

The semiconductor pattern 200 may be positioned at each layer of the memory cells.

One end of the semiconductor pattern 200 in the second direction D2 may connect to the bit line BL. The other end in the second direction D2 of the semiconductor pattern 200 may connect to the data storage pattern DS.

The semiconductor patterns 200 may be spaced apart in the first direction D1 along the extending direction of the bit line BL. Additionally, the semiconductor patterns 200 may be spaced apart in the third direction D3 along the spaced apart direction of the bit line BL. For example, the semiconductor pattern 200 may have a length in the third direction D3 that is greater than a length in the first direction D1, and the semiconductor pattern 200 may have a spacing distance in the first direction D1 that is greater than a spacing distance in the third direction D3.

The semiconductor pattern 200 may be positioned between the gate insulating pattern layers 220. The semiconductor pattern 200 may be surrounded by the gate insulating liner 280. The semiconductor pattern 200 may be spaced apart from the word line WL with the gate insulating layer Gox interposed therebetween. The semiconductor pattern 200 may be positioned between the first word line WL1 and the second word line WL2.

At least a portion of the semiconductor pattern 200 may overlap with the word line WL in the first direction D1. At least a portion of the semiconductor pattern 200 may overlap with the first spacer 140 and the capping pattern 145 in the first direction D1.

One side in the second direction D2 of the semiconductor patterns 200 may connect to the first oxide semiconductor layer 420. For example, the first oxide semiconductor layer 420 and the semiconductor patterns 200 may constitute a single body. In other words, the first oxide semiconductor layer 420 and the semiconductor pattern 200 may be combined to form an integral unit.

As described below, when replacing the preliminary semiconductor patterns 170 with the semiconductor patterns 200, the first oxide semiconductor layer 420 of the bit line BL connected with the semiconductor patterns 200 may be formed together. As the first oxide semiconductor layer 420 of the bit line BL and the semiconductor patterns 200 are simultaneously formed in one process, the first oxide semiconductor layer 420 and the semiconductor patterns 200 may constitute a single body. In other words, the first oxide semiconductor layer 420 and the semiconductor patterns 200 may include an oxide semiconductor material having the same composition, and their boundary may not be distinguishable.

As a result, the breakage defects of the semiconductor patterns 200 and the bit line BL may be eliminated. In addition, the contact area between the bit line BL and the semiconductor patterns 200 is increased, which may reduce the contact resistance between the semiconductor patterns 200 and the bit line BL, thereby improving the operational characteristics of the semiconductor device.

The semiconductor patterns 200 may include the same oxide semiconductor material as the first oxide semiconductor layer 420. The oxide semiconductor material may be a combination of at least two of In, Ga, Zn, Al, Sn, and Hf, but is not limited thereto. The oxide semiconductor material may further include materials such as Si, Mg, Ta, La, Nd, Ce, Sc, Cr, Co, Nb, Mo, Ba, Gd, Ti, W, Pd, Ru, Ni, or Mn in the composition. For example, the semiconductor pattern 200 may include IGZO (indium gallium zinc oxide), Sn-IGZO (tin-doped indium gallium zinc oxide), ITZO (indium tin zinc oxide), IZO (indium zinc oxide), ZnO (zinc oxide), ZTO (zinc tin oxide), ZnON (zinc oxynitride), ZZTO (zirconium zinc tin oxide), SnO (tin oxide), HIZO (hafnium indium zinc oxide), GZTO (gallium zinc tin oxide), AZTO (aluminium zinc tin oxide), YGZO (ytterbium gallium zinc oxide), IGO (indium gallium oxide), IWO (indium tungsten oxide), YZO (yttrium zinc oxide), or a combination thereof.

In some embodiments, the semiconductor pattern 200 may have impurity regions and a channel region between the impurity regions. The impurity regions may correspond to the source/drain regions of the memory cell transistor. The impurity regions may be regions doped with impurities in the semiconductor pattern 200. The impurity regions may have an n-type or p-type conductivity type. The impurity regions may be positioned adjacent to both ends in the second direction D2 of the semiconductor pattern 200.

The data storage pattern DS may connect electrically with the semiconductor patterns 200. The data storage pattern DS serves as a memory element capable of storing data, for example, a memory element utilizing a capacitor, a memory element utilizing a magnetic tunnel junction pattern, or a memory element utilizing a variable resistor including a phase change material.

For example, the data storage pattern DS may be a capacitor. The data storage pattern DS may include a first electrode 310 and a second electrode 330 spaced apart from the first electrode 310, and a dielectric layer 320 positioned between the first electrode 310 and the second electrode 330.

The first electrode 310 may connect to one side of the semiconductor pattern 200 in the second direction D2, and the dielectric layer 320 may cover the first electrode 310, and the second electrode 330 may cover the dielectric layer 320.

For example, in the second direction D2, one side of the first electrode 310 may connect to one side of the semiconductor pattern 200. The dielectric layer 320 may conformally cover the other side of the first electrode 310 in the second direction D2, the upper surface and lower surface of the first electrode 310, and one side and the other side of the first electrode 310 in the third direction D3. The second electrode 330 may cover the first electrode 310 with the dielectric layer 320 interposed therebetween. One second electrode 330 may cover the first electrodes 310 integrally with the dielectric layers 320 interposed therebetween. As a result, the data storage patterns DS stacked in the first direction D1 may share one second electrode 330.

A second spacer 340 may be filled between the data storage patterns DS. The second spacer 340 may cover the second electrode 330. For example, the second spacer 340 may fill the space defined by the second electrode 330. In other words, the second spacer 340 may fill the space between the data storage patterns DS positioned spaced apart in each of the first direction D1, the second direction D2, and the third direction D3. In some embodiments, the space between the data storage patterns DS may be filled with the second electrode 330 instead of the second spacer 340.

FIGS. 1 to 5 illustrate a case where the first electrode 310 has a column shape with a filled interior space. In some embodiments, the first electrode 310 may have a cylinder shape with a hollow interior space. In this case, the dielectric layer 320 and the second electrode 330 may be positioned on the interior space of the first electrode 310, thereby further increasing the surface area of the data storage pattern DS.

The first electrode 310 and the second electrode 330 may each include a metal material such as titanium, tantalum, tungsten, copper, or aluminum, a conductive metal nitride such as titanium nitride or tantalum nitride, or a doped semiconductor material such as doped silicon or doped germanium.

The dielectric layer 320 may include a dielectric, ferroelectric, antiferromagnetic, or a combination thereof. The dielectric may include a high-k material. For example, the dielectric may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

As described below, the semiconductor device according to one embodiment is manufactured by first forming the data storage pattern DS on one side of preliminary semiconductor patterns 170, forming a word line WL on the other side of the preliminary semiconductor patterns 170, and then replacing the preliminary semiconductor patterns 170 with the semiconductor patterns 200 before forming the bit line BL.

Since the data storage pattern DS is formed before the word line WL, the semiconductor patterns 200, and the bit line BL, the gate insulating layer Gox may include the gate insulating pattern layer 220 positioned towards the semiconductor pattern 200 and the gate insulating liner 280 positioned towards the word line WL. Furthermore, the gate insulating liner 280 may have the first insulating liner portion 281 positioned between the word line WL and the gate insulating pattern layer 220, and the second insulating liner portion 282 positioned between the word line WL and the data storage pattern DS. Additionally, the capping pattern 145 may have the first capping portion 146 positioned between the word line separation layer 150 and the first insulating liner portion 281, and the second capping portion 147 positioned between the word line separation layer 150 and the second insulating liner portion 282.

In other words, when forming the data storage pattern DS first, the second insulating liner portion 282 positioned between the word line WL and the data storage pattern DS may be necessary to ensure that the word line WL is spaced apart from the second electrode 330 of the data storage pattern DS. Also, as described later, when the first and second word lines WL1, WL2 are formed by cutting the preliminary gate conductive layer PGL after forming the preliminary gate conductive layer PGL, since the data storage pattern DS is already formed and prevents the cutting of the preliminary gate conductive layer PGL, the second capping portion 147 positioned between the word line separation layer 150 and the second insulating liner portion 282 may be required.

The gate insulating layer Gox may include the gate insulating pattern layer 220 and the gate insulating liner 280, preventing hydrogen from penetrating the semiconductor pattern 200 and thereby preventing the semiconductor pattern 200 from deteriorating, which may improve operational reliability.

Also, by first forming the data storage pattern DS, then forming the word line WL, and replacing the preliminary semiconductor patterns 170 with the semiconductor patterns 200 before forming the bit line BL, it may minimize the damage caused by chemicals and heat applied to the semiconductor pattern 200 including oxide semiconductor material, and improve the characteristics of the semiconductor pattern 200.

For example, when preliminary semiconductor patterns 170 are first replaced with the semiconductor patterns 200 and then word line WL and the bit line BL are formed, damage by chemicals may occur to the semiconductor patterns 200 including an oxide semiconductor material, and exposure to heat may lead to deterioration of the characteristics of the semiconductor patterns 200. For example, when the preliminary semiconductor patterns 170 are first replaced with the semiconductor patterns 200, during the process of forming the word line WL and the bit line BL, the semiconductor patterns 200 may be exposed to the outside more than seven times, and may be exposed to three major heat processes such as the step to form the gate insulating liner 280 (about 150° C.), the step to form the word line WL (300° C. to 450° C.), and the step to form the bit line BL (300° C. to 450° C.).

On the other hand, in the case where the word line WL is formed first and the preliminary semiconductor patterns 170 are replaced with the semiconductor patterns 200 before forming the bit line BL, the semiconductor patterns 200 may be exposed to the outside only once in the process of forming the second oxide semiconductor layer 430, and may be exposed to the heat process only once in the process of forming the bit line BL (300° C. to 450° C.).

Furthermore, when replacing the preliminary semiconductor patterns 170 with the semiconductor patterns 200, the first oxide semiconductor layer 420 of the bit line BL connected to the semiconductor patterns 200 is formed together. As the first oxide semiconductor layer 420 of the bit line BL and the semiconductor patterns 200 are simultaneously formed in one process, the first oxide semiconductor layer 420 and the semiconductor patterns 200 may constitute a single body, thereby eliminating disconnection defects between the semiconductor patterns 200 and the bit line BL. Additionally, as the contact area between the bit line BL and the semiconductor patterns 200 increases, the contact resistance between the semiconductor patterns 200 and the bit line BL may decrease, enhancing the operational characteristics.

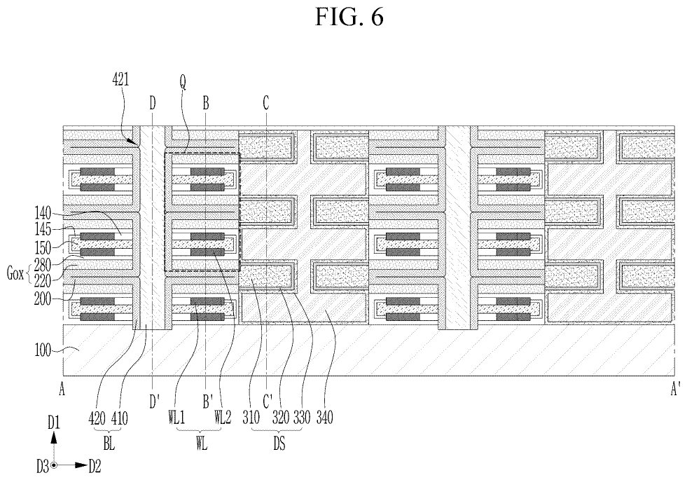

Hereinafter, referring to FIGS. 6 to 11, semiconductor devices according to various embodiments will be described.

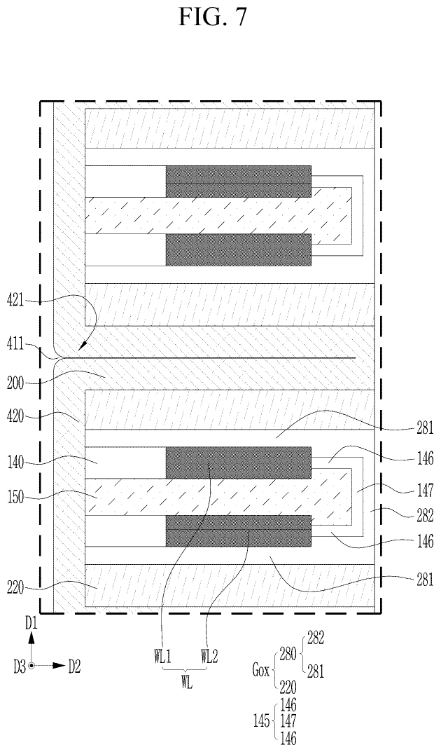

FIG. 6 is a cross-sectional view taken along line A-A′ of FIG. 1, corresponding to FIG. 2. FIG. 7 is a cross-sectional view enlarging the Q portion of FIG. 6.

Embodiments shown in FIGS. 6 and 7 is substantially the same as embodiments shown in FIGS. 1 to 5, so the explanation for these parts will be omitted and the differences will be primarily explained. Additionally, the same reference numerals are used for components that are the same as in the preceding embodiment.

Referring to FIGS. 6 and 7, the first oxide semiconductor layer 420 of the bit line BL may have a concave portion 421 on the side facing the core conductive layer 410, and the concave portion 421 may be indented with respect to the semiconductor pattern.

As described above, when replacing the preliminary semiconductor patterns 170 with the semiconductor patterns 200, the first oxide semiconductor layer 420 of the bit line BL connected to the semiconductor patterns 200 is formed together.

The first oxide semiconductor layer 420 of the bit line BL and the semiconductor patterns 200 may be simultaneously formed in one process. For example, the first oxide semiconductor layer 420 and semiconductor patterns 200 may be formed by the oxide semiconductor material conformally covering the surface of a space exposed by a fifth inner region INR5 and fourth trench TR4 to be described later. At this time, the surface exposed as the fourth trench TR4 of the oxide semiconductor material formed on the corner where one side in the second direction D2 of the gate insulating pattern layer 220 meets one side in the first direction D1, which is the part where the first oxide semiconductor layer 420 and the semiconductor patterns 200 are connected, may have a rounded shape in cross-section. As the part where the first oxide semiconductor layer 420 and the semiconductor patterns 200 are connected may have a rounded shape in cross-Attorney section, the first oxide semiconductor layer 420 may have concave portions 421 in positions corresponding to each of the semiconductor patterns 200. The concave portion 421 may have a size and shape corresponding to the size and shape in the second direction D2 and the third direction D3 of the semiconductor pattern 200.

Also, when forming the semiconductor pattern 200 by filling the fifth inner region INR5 with the oxide semiconductor material, the oxide semiconductor material simultaneously grows from the lower surface in the first direction D1 of one gate insulation pattern layer 220 and from the upper surface in the first direction D1 of the other gate insulation pattern layer 220. As it fills the fifth inner region INR5 meeting at approximately the midpoint in the first direction D1 of the fifth inner region INR5, the semiconductor pattern 200 may have an interface internally. The interface of the semiconductor pattern 200 extends in the second direction D2 and its end may meet the concave portion 421. However, it is not limited to this, as the semiconductor pattern 200 comprises the same material, the interface may not be indistinguishable.

Additionally, as described below, the bit line BL is formed after forming the first oxide semiconductor layer 420 by filling the empty space between the first oxide semiconductor layers 420 with the core conductive layer 410. Therefore, the core conductive layer 410 may have a first convex portion 411 that protrudes toward the concave portion 421 of the first oxide semiconductor layer 420. The core conductive layer 410 may have first convex portions 411 positioned at positions corresponding to each of the concave portions 421 of the first oxide semiconductor layer 420. The first convex portion 411 may have a size and shape corresponding to the size and shape in the second direction D2 and the third direction D3 of the concave portion 421.

The first oxide semiconductor layer 420, by including the concave portion 421, more smoothly connects with the semiconductor pattern 200, which may eliminate the breakage defect between the semiconductor patterns 200 and the bit line BL. Additionally, as the contact area between the bit line BL and the semiconductor pattern 200 increases, the contact resistance between the semiconductor pattern 200 and the bit line BL may decrease, which may improve the operational characteristics.

Meanwhile, as described hereinafter, after forming the first oxide semiconductor layer 420, a portion of the surface exposed to the fourth trench TR4 of the first oxide semiconductor layer 420 may be removed through a cleaning process. For example, the cleaning process may be performed to the extent of removing the concave portions 421 of the first oxide semiconductor layer 420. When the concave portion 421 are removed by the cleaning process, a length in the second direction D2 of the first oxide semiconductor layer 420 may be reduced, and as shown in FIG. 2, the first oxide semiconductor layer 420 may not have the concave portions 421. Meanwhile, if the cleaning process is not performed, as shown in FIG. 6, the first oxide semiconductor layer 420 may have the concave portion 421.

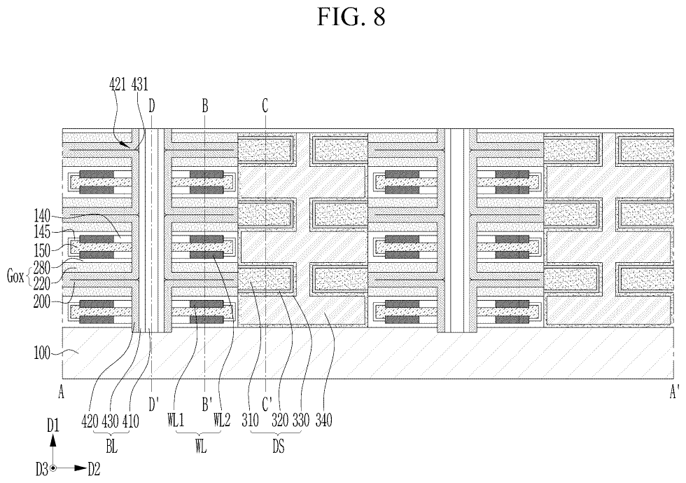

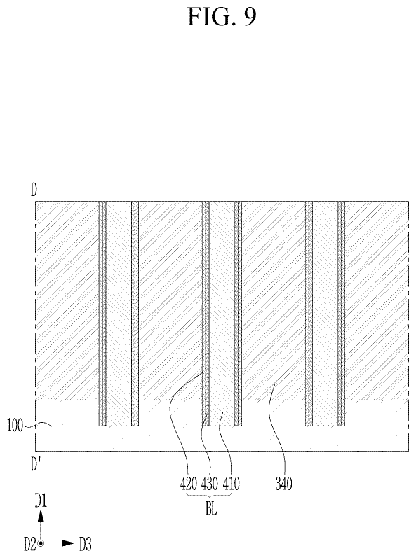

FIG. 8 is a cross-sectional view taken along line A-A′ of FIG. 1, corresponding to FIG. 2. FIG. 9 is a cross-sectional view taken along line D-D′ of FIG. 1, corresponding to FIG. 4.

Embodiments shown in FIGS. 8 and 9 are substantially the same as embodiments shown in FIGS. 1 to 5, so the explanation for these parts will be omitted and the differences will be primarily explained. Additionally, the same reference numerals are used for components that are the same as in the preceding embodiment.

FIGS. 8 and 9 illustrate that the bit line BL may further include a second oxide semiconductor layer 430.

The second oxide semiconductor layer 430 may be positioned between the core conductive layer 410 and the first oxide semiconductor layer 420. The second oxide semiconductor layer 430 may extend in the first direction D1 along the core conductive layer 410. The second oxide semiconductor layer 430 may conformally cover the side of the core conductive layer 410. For example, the second oxide semiconductor layer 430 may have a ring shape surrounding the core conductive layer 410, continuously extending in a plane. Moreover, corresponding to the planar shape of the core conductive layer 410, the planar shape of the second oxide semiconductor layer 430 may be a quadrangular ring, a polygonal ring having five or more angles, a circular ring, or an elliptical ring.

The second oxide semiconductor layer 430 may include an oxide semiconductor material. The oxide semiconductor material may be a combination of at least two of In, Ga, Zn, Al, Sn, and Hf, but is not limited thereto. The oxide semiconductor material may further include materials such as Si, Mg, Ta, La, Nd, Ce, Sc, Cr, Co, Nb, Mo, Ba, Gd, Ti, W, Pd, Ru, Ni, or Mn in the composition. For example, the second oxide semiconductor layer 430 may include IGZO (indium gallium zinc oxide), Sn-IGZO (tin-doped indium gallium zinc oxide), ITZO (indium tin zinc oxide), IZO (indium zinc oxide), ZnO (zinc oxide), ZTO (zinc tin oxide), ZnON (zinc oxynitride), ZZTO (zirconium zinc tin oxide), SnO (tin oxide), HIZO (hafnium indium zinc oxide), GZTO (gallium zinc tin oxide), AZTO (aluminium zinc tin oxide), YGZO (ytterbium gallium zinc oxide), IGO (indium gallium oxide), IWO (indium tungsten oxide), YZO (yttrium zinc oxide), or combinations thereof.

However, unlike the first oxide semiconductor layer 420, the second oxide semiconductor layer 430 is not formed together with the first oxide semiconductor layer 420 and semiconductor patterns 200, but is separately formed in a different process. Accordingly, the second oxide semiconductor layer 430 may include an oxide semiconductor material different from the first oxide semiconductor layer 420 and semiconductor patterns 200. The core conductive layer 410 may be spaced apart from the first oxide semiconductor layer 420 and semiconductor patterns 200 with the second oxide semiconductor layer 430 interposed therebetween.

In some embodiments, as shown in FIG. 6, when the first oxide semiconductor layer 420 is having a concave portion 421, the second oxide semiconductor layer 430 may have a second convex portion 431 protruding toward the concave portion 421 of the first oxide semiconductor layer 420. In this case, the first oxide semiconductor layer 420 may have a concave portion 421 on the side facing the second oxide semiconductor layer 430. The concave portion 421 may be indented with respect to the semiconductor pattern 200. The second oxide semiconductor layer 430 may have a second convex portions 431 at positions corresponding to each concave portion 421 of the first oxide semiconductor layer 420. The second convex portion 431 may have a size and shape corresponding to the size and shape in the second direction D2 and the third direction D3 of the concave portion 421. In other embodiments, the side of the first oxide semiconductor layer 420 facing the core conductive layer 410 may have a flat surface as illustrated in FIG. 2, in which case the second oxide semiconductor layer 430 may have a flat surface to correspond with the flat surface of the first oxide semiconductor layer 420.

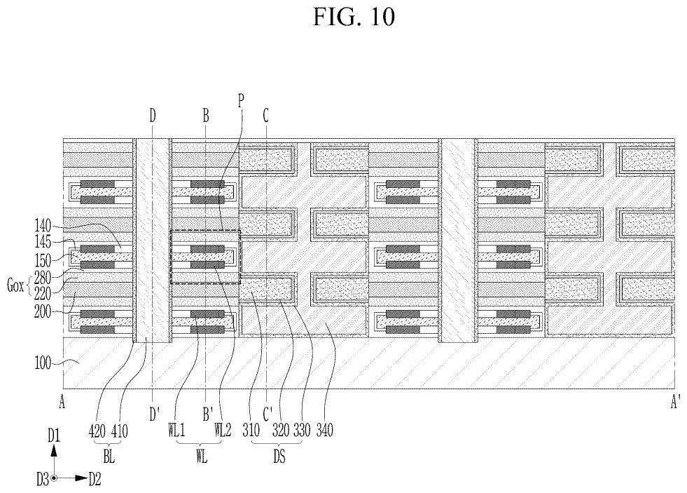

FIG. 10 is a cross-sectional view taken along the line A-A′ of FIG. 1, corresponding to FIG. 2.

Embodiments shown in FIG. 10 are substantially the same as embodiments shown in FIGS. 1 to 5, so the explanation for these parts will be omitted and the differences will be primarily explained. Additionally, the same reference numerals are used for components that are the same as in the preceding embodiment.

In FIG. 2, as the first oxide semiconductor layer 420 of the bit line BL and the semiconductor patterns 200 are simultaneously formed in one process, there is illustrated a case where the first oxide semiconductor layer 420 and the semiconductor patterns 200 constitute a single body. In other words, the first oxide semiconductor layer 420 and the semiconductor patterns 200 may include an oxide semiconductor material having the same composition, and their boundary may not be distinguishable.

In FIG. 10, a case is illustrated where the boundary between the first oxide semiconductor layer 420 and the semiconductor patterns 200 is distinguished. In this case, the first oxide semiconductor layer 420 is not formed together with the semiconductor patterns 200, and may be formed separately in a different process. The core conductive layer 410 may be spaced apart from the semiconductor patterns 200, with the first oxide semiconductor layer 420 interposed therebetween. The first oxide semiconductor layer 420 of the bit line BL may not have a concave portion 421 indented with respect to the semiconductor pattern 200 on the side facing the core conductive layer 410.

At this time, the first oxide semiconductor layer 420 may include an oxide semiconductor material different from the semiconductor pattern 200. However, it is not limited thereto, and in this case, the first oxide semiconductor layer 420 may also include the same oxide semiconductor material as the semiconductor pattern 200.

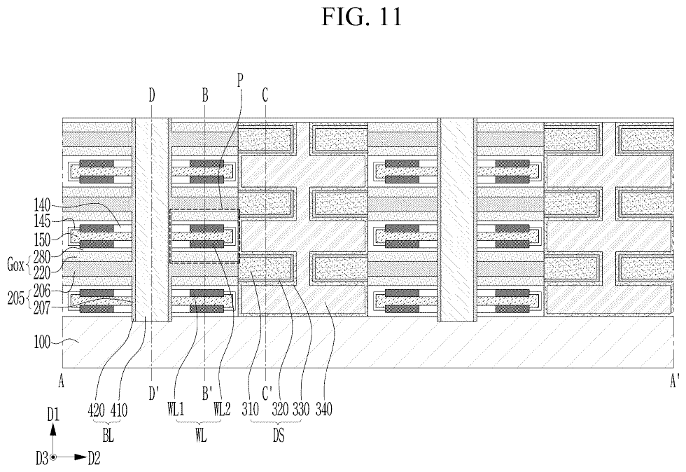

FIG. 11 is a cross-sectional view taken along line A-A′ of FIG. 1, corresponding to FIG. 2.

Embodiments shown in FIG. 11 are substantially the same as embodiments shown in FIGS. 1 to 5, so the explanation for these parts will be omitted and the differences will be primarily explained. Additionally, the same reference numerals are used for components that are the same as in the preceding embodiment.

In FIG. 2, when the first oxide semiconductor layer 420 of the bit line BL and the semiconductor patterns 200 are simultaneously formed in one process, the bit line BL is explained to include the first oxide semiconductor layer 420.

However, as the first oxide semiconductor layer 420 and the semiconductor patterns 200 are simultaneously formed in one process, as described above, the first oxide semiconductor layer 420 and the semiconductor patterns 200 are combined to form an integral unit, may include an oxide semiconductor material having the same composition, and their boundary may not be distinguishable.

Thus, the first oxide semiconductor layer 420 may not only be described as a component of the bit line BL but also as a component of the semiconductor structure 205, having first portions 206 corresponding to the semiconductor patterns 200 and second portion 207 corresponding to the first oxide semiconductor layer 420.

Referring to FIG. 11, it shows a case where the semiconductor structure 205 has the first portions 206 corresponding to the semiconductor patterns 200 in FIG. 2 and the second portion 207 corresponding to the first oxide semiconductor layer 420 in FIG. 2.

The first portions 206 of the semiconductor structure 205 may be spaced apart from each other in the first direction D1. Each first portion 206 may overlap with the word line WL in the first direction D1. One side in the second direction D2 of the first portions 206 may connect to the second portion 207. The other side in the second direction D2 of the first portions 206 may connect to the data storage pattern DS.

The second portion 207 of the semiconductor structure 205 may extend in the first direction D1. The second portion 207 may extend long along the bit line BL in the first direction D1. The second portion 207 may connect the first portions 206 that are spaced apart in the first direction D1 while extending in the first direction D1. The second portion 207 may be positioned between the bit line BL and the first portions 206.

The description for the first portion 206 is identical to the description for the aforementioned semiconductor patterns 200, and the description for the second portion 207 is identical to the description for the aforementioned first oxide semiconductor layer 420, thus repetitive descriptions are omitted.

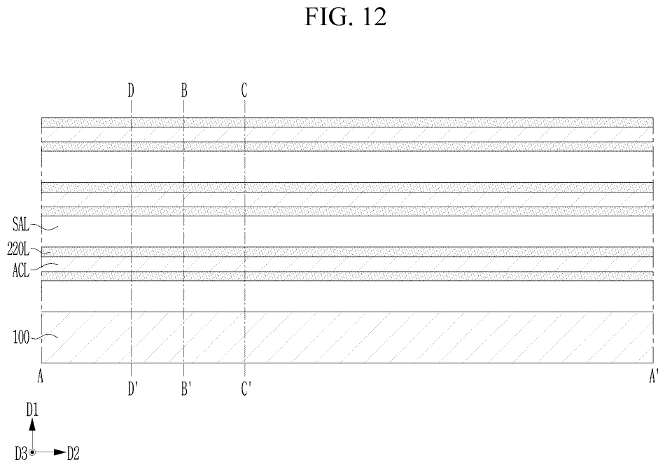

Hereinafter, a method of manufacturing a semiconductor device will be described with reference to FIGS. 12 to 67.

FIGS. 12 to 67 are cross-sectional views showing a method of manufacturing a semiconductor device in process order. FIGS. 12 to 67 illustrate the method of manufacturing a semiconductor device according to FIGS. 1 to 5.

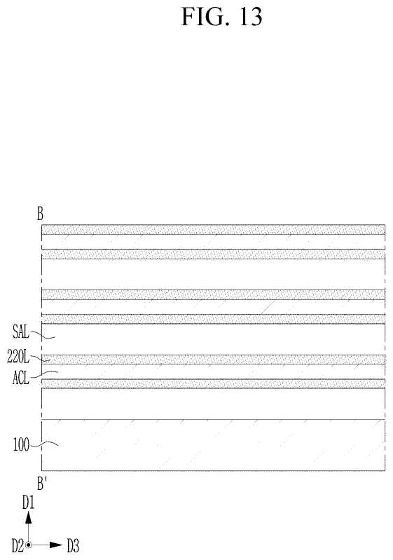

FIG. 12 is a cross-sectional view taken along line A-A′ of FIG. 1, corresponding to FIG. 2. FIG. 13 is a cross-sectional view taken along line B-B′ of FIG. 1, corresponding to FIG. 3.

Referring to FIGS. 12 and 13, sacrificial layers SAL and active layers ACL may be alternately stacked on a substrate 100. Each of the sacrificial layers SAL and the active layers ACL may include a semiconductor material. The sacrificial layers SAL may include a material having an etching selectivity with the active layers ACL. Accordingly, during the removal process of the sacrificial layers SAL to be described later, even if the sacrificial layers SAL are removed, the active layers ACL may not be removed or may be minimally removed. For example, the active layers ACL may include silicon (Si), germanium (Ge), or silicon-germanium (SiGe), and the sacrificial layers SAL may include one that is different from the active layers ACL among silicon (Si), germanium (Ge), or silicon-germanium (SiGe). For example, the active layers ACL may include silicon (Si), and the sacrificial layers SAL may include silicon-germanium (SiGe). The thickness of the sacrificial layers SAL may be greater than that of the active layers ACL.

In some embodiments, a gate insulating pattern material layer 220L may be positioned between the sacrificial layer SAL and the active layer ACL. For example, on a substrate 100, the sacrificial layer SAL, the gate insulating pattern material layer 220L, the active layer ACL, and the gate insulating pattern material layer 220L may be laminated in order.

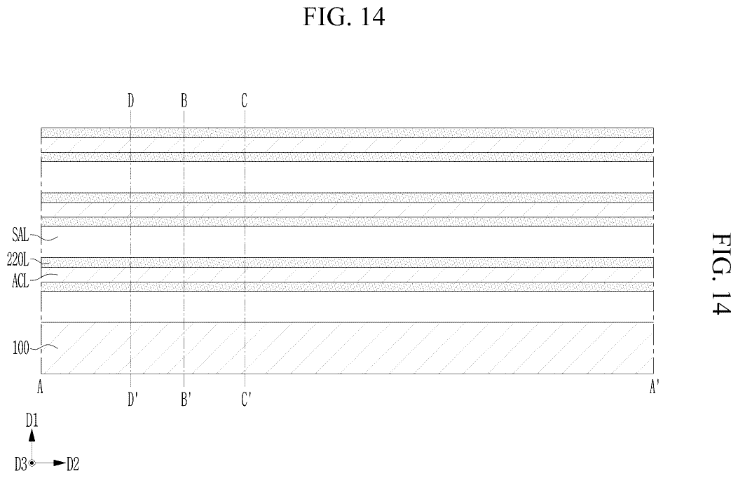

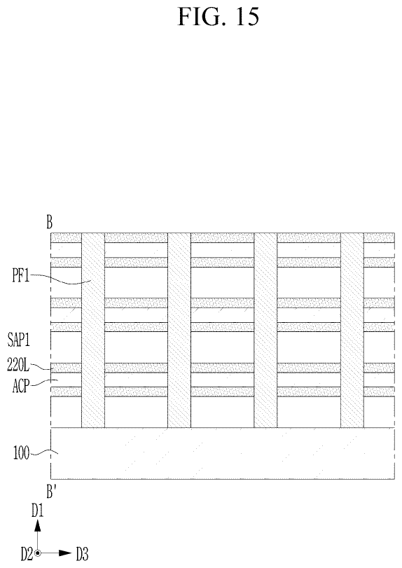

FIG. 14 is a cross-sectional view taken along line A-A′ of FIG. 1, corresponding to FIG. 2. FIG. 15 is a cross-sectional view taken along line B-B′ of FIG. 1, corresponding to FIG. 3.

Referring to FIGS. 14 and 15, first sacrificial patterns SAP1 and first preliminary semiconductor patterns ACP spaced apart in the third direction D3 are formed.

First, the sacrificial layers SAL, the active layers ACL, and the gate insulating pattern material layers 220L may be patterned to form first trenches. The first trenches may extend in the second direction D2 and may be formed to be spaced apart from each other along the third direction D3. The first trenches may be formed from the topmost sacrificial layer SAL or active layer ACL down to the substrate 100 in the first direction D1, so that a portion of the upper surface of the substrate 100 may be exposed externally.

Forming the first trenches, the patterned and remaining sacrificial layers SAL may constitute the first sacrificial patterns SAP1, and the patterned and remaining active layers ACL may constitute the first preliminary semiconductor patterns ACP. The first sacrificial patterns SAP1 and the first preliminary semiconductor patterns ACP may extend in the second direction D2 between the first trenches, which are spaced apart in the third direction D3.

In some embodiments, the first trenches may extend in the second direction D2 and may be formed to be spaced apart from each other along the second direction D2 and the third direction D3. Accordingly, the first sacrificial patterns SAP1 and the first preliminary semiconductor patterns ACP may be positioned between the first trenches spaced apart in the third direction D3 and may include regions extending in the second direction D2 and regions that intersect the regions extending in the second direction D2 and extend in the third direction D3.

After forming the first trenches, first preliminary filling patterns PF1 may fill the first trenches. The first preliminary filling patterns PF1 may cover the upper surface of the exposed substrate 100. The first preliminary filling patterns PF1 may be spaced apart from each other in the third direction D3 by the first preliminary semiconductor patterns ACP and the first sacrificial patterns SAP1. For example, the first preliminary filling pattern PF1 may include an insulating material and, for example, may include silicon nitride.

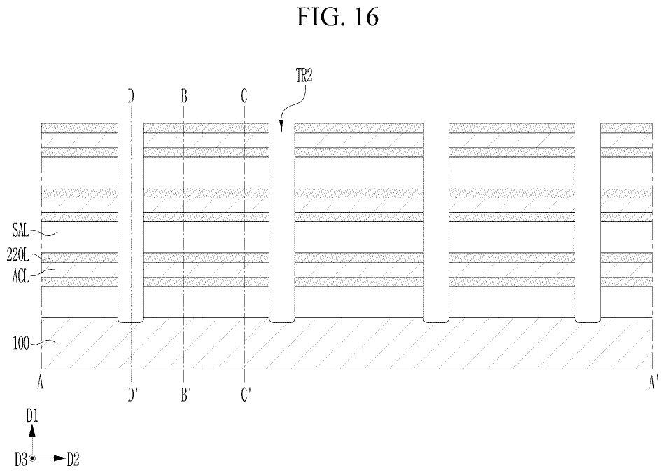

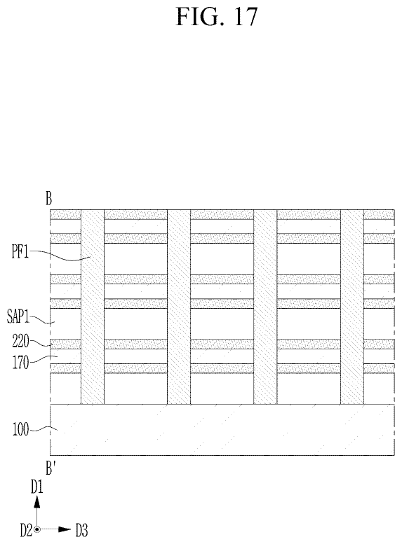

FIG. 16 is a cross-sectional view taken along the line A-A′ of FIG. 1, corresponding to FIG. 2. FIG. 17 is a cross-sectional view taken along the line B-B′ of FIG. 1, corresponding to FIG. 3.

Referring to FIGS. 16 and 17, the first sacrificial patterns SAP1 and the second preliminary semiconductor patterns 170 may be alternately stacked, and the gate insulation pattern layers 220 may be interposed between the first sacrificial patterns SAP1 and the second preliminary semiconductor patterns 170 to form a preliminary stack.

First, after forming the first preliminary filling patterns PF1, second trenches TR2 may be formed. The second trenches TR2 may be formed on both sides of the first sacrificial patterns SAP1, the first preliminary semiconductor patterns ACP, and the gate insulating pattern material layer 220L in the second direction D2.

For example, the second trenches TR2 may be formed by patterning a portion of the region extending in the third direction D3 among the first sacrificial patterns SAP1, the first preliminary semiconductor patterns ACP, and the gate insulating pattern material layers 220L on a plane. In some embodiments, forming the second trench TR2 may include the removal of a portion of the top of the substrate 100.

Forming the second trench TR2, the patterned and remaining first preliminary semiconductor patterns ACP may constitute the second preliminary semiconductor patterns 170. The patterned and remaining gate insulating pattern material layers 220L may constitute the gate insulating pattern layers 220.

The second trench TR2 may expose one side in the second direction D2 of the first sacrificial patterns SAP1, the second preliminary semiconductor patterns 170, and the gate insulating pattern layers 220 to the outside. The second trench TR2 may expose a portion of the upper surface of the substrate 100 to the outside.

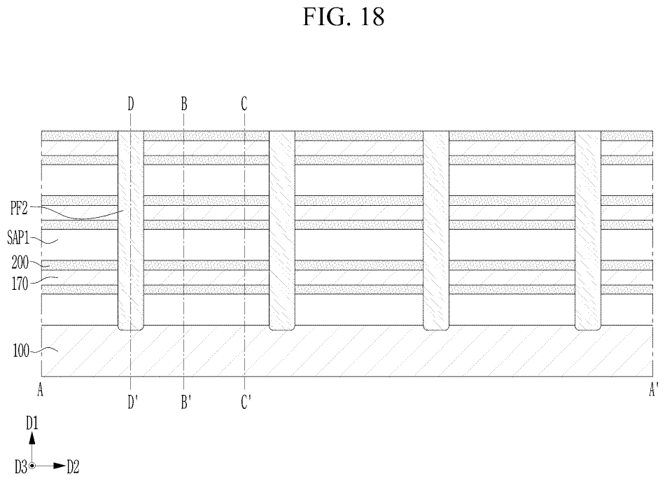

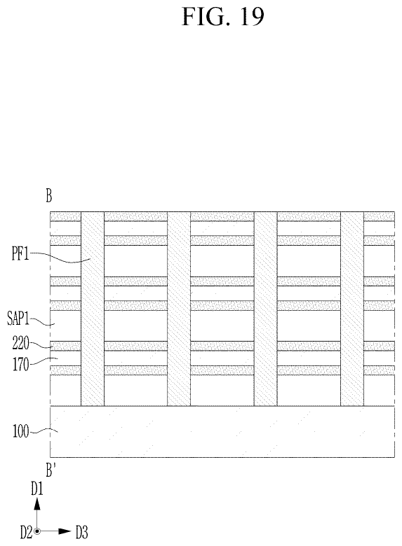

FIG. 18 is a cross-sectional view taken along line A-A′ of FIG. 1, corresponding to FIG. 2. FIG. 19 is a cross-sectional view taken along line B-B′ of FIG. 1, corresponding to FIG. 3.

Referring to FIGS. 18 and 19, after forming the second trenches TR2, the second preliminary filling patterns PF2 may fill the second trenches TR2. The second preliminary filling patterns PF2 may cover the upper surface of the exposed substrate 100. The second preliminary filling patterns PF2 may be spaced apart in the second direction D2 by the first sacrificial patterns SAP1, the second preliminary semiconductor patterns 170, and the gate insulating pattern layer 220. For example, the second preliminary filling pattern PF2 may include an insulating material and, for example, may include silicon oxide.

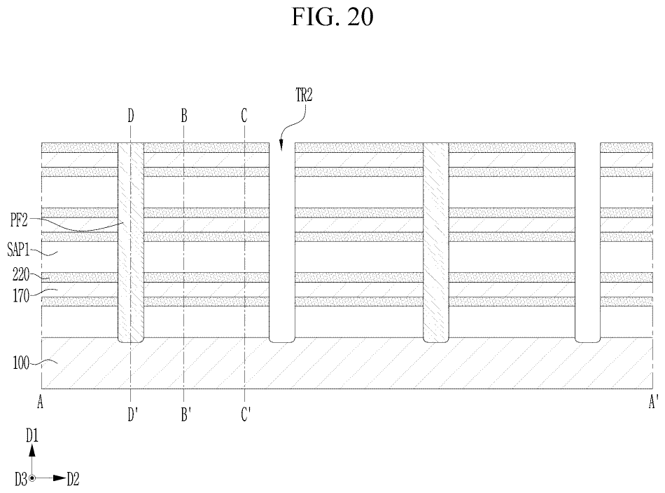

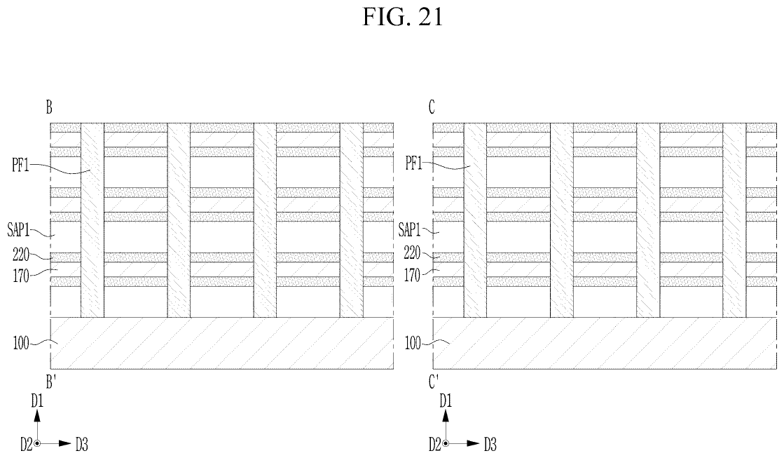

FIG. 20 is a cross-sectional view taken along line A-A′ of FIG. 1, corresponding to FIG. 2. FIG. 21 is a cross-sectional view taken along lines B-B′ and C-C′ of FIG. 1, corresponding to FIG. 3.

Referring to FIGS. 20 and 21, a portion of the second preliminary filling patterns PF2 may be removed. For example, the second preliminary filling patterns PF2 positioned in a region where the data storage patterns DS will be formed may be removed.

For example, the second preliminary filling patterns PF2 may be alternately removed in the second direction D2. In other words, one of the second preliminary filling patterns PF2 is left, and the next second preliminary filling pattern PF2 in the second direction D2 is removed, the next second preliminary filling pattern PF2 in the second direction D2 is left, and the next second preliminary filling pattern PF2 in the second direction D2 may be removed.

The removal of the second preliminary filling patterns PF2 may be accomplished by using a photoresist process to expose only the second preliminary filling patterns PF2 to be removed, followed by removal using a wet or dry etching process.

As some of the second preliminary filling patterns PF2 are removed, some of the second trenches TR2 may be re-exposed. Additionally, by the second trench TR2, the other side in the second direction D2 of the first sacrificial patterns SAP1, the second preliminary semiconductor patterns 170, and the gate insulation pattern layer 220 may be exposed to the outside. By the second trench TR2, a portion of the upper surface of the substrate 100 may be exposed to the outside.

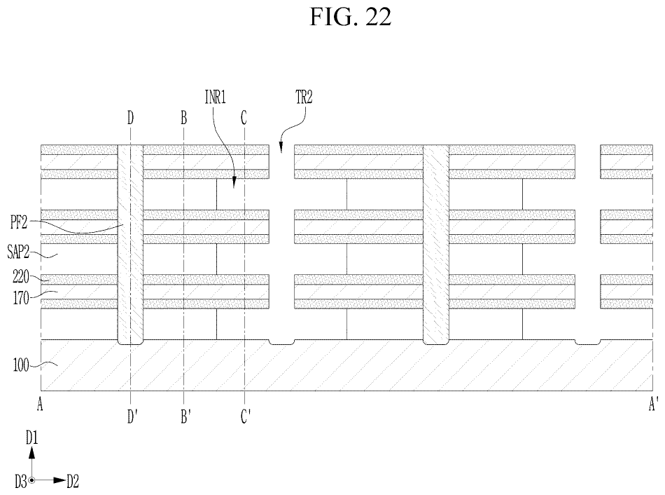

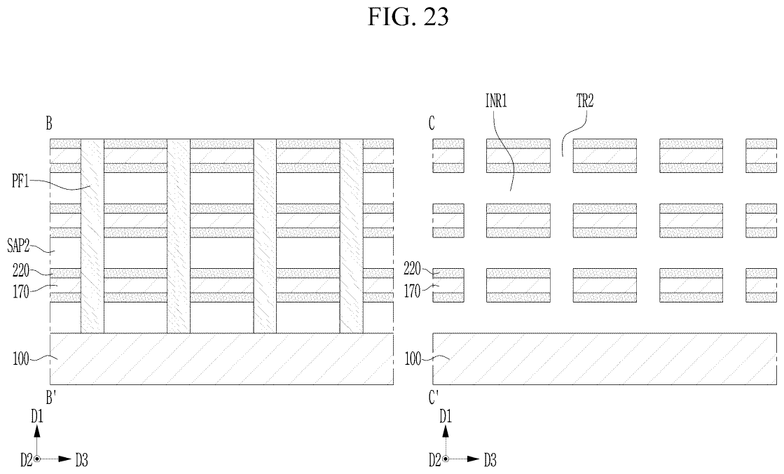

FIG. 22 is a cross-sectional view cut along the A-A′ line of FIG. 1, corresponding to FIG. 2. FIG. 23 is a cross-sectional view cut along the B-B′ line and the C-C′ line of FIG. 1, corresponding to FIG. 3.

Referring to FIGS. 22 and 23, the other side of the first sacrificial patterns SAP1, exposed by the second trench TR2, may be selectively removed through a selective etching process in a second direction D2. The remaining first sacrificial patterns SAP1, after removal through the selective etching process, may constitute the second sacrificial patterns SAP2.

During the selective etching process, portions of each of the first preliminary filling patterns PF1 may be removed together, exposing a portion of the upper surface of the substrate 100. The sidewalls of the first preliminary filling patterns PF1 in the second direction D2 may align with the sidewalls of the sacrificial patterns SAP2 in the second direction D2.

One side in the second direction of the first sacrificial patterns SAP1 is selectively removed, and the first inner regions INR1 may be formed between the second preliminary semiconductor patterns 170 neighboring in the first direction D1.

For example, selectively removing the other side of the first sacrificial pattern SAP1 in the second direction D2 exposed by the second trench TR2 may include removing a portion of the other side of the first preliminary filling pattern PF1 and the first sacrificial pattern SAP1 in the second direction D2 through a selective etching process such as wet etching or dry etching.

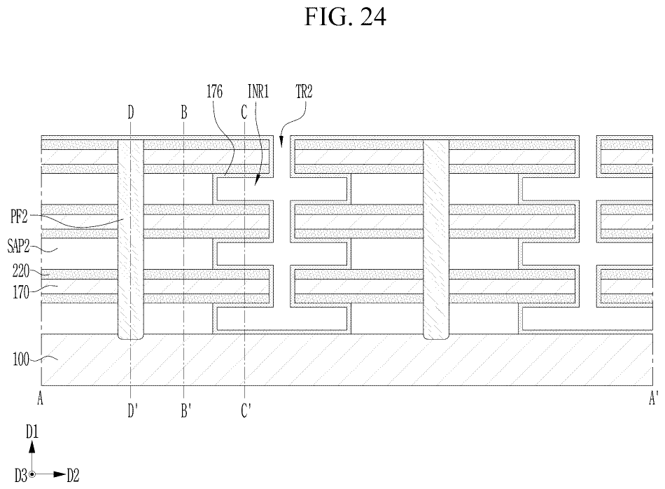

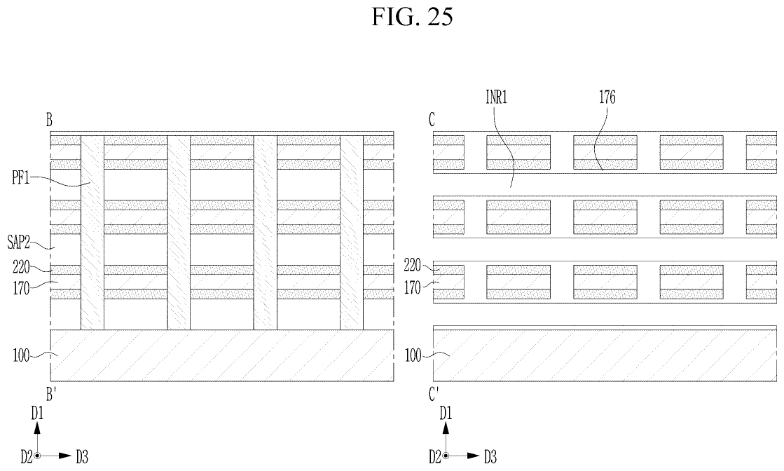

FIG. 24 is a cross-sectional view taken along the A-A′ line of FIG. 1, corresponding to FIG. 2. FIG. 25 is a cross-sectional view taken along the B-B′ line and C-C′ line of FIG. 1, corresponding to FIG. 3.

Referring to FIGS. 24 and 25, the first sacrificial insulating pattern 176 may be formed on the other side in the second direction D2 of the second preliminary semiconductor patterns 170, on the other side in the second direction D2 of the second sacrificial patterns SAP2, and on the other side in the second direction D2 and one side in the first direction D1 of the gate insulating pattern layers 220 exposed by removing the first sacrificial patterns SAP1. Additionally, the first sacrificial insulating pattern 176 may also be formed on the upper surface of the substrate 100 exposed by the second trench TR2 and the first inner regions INR1.

For example, the first sacrificial insulating pattern 176 may extend in the third direction D3. The first sacrificial insulating pattern 176 may extend in the third direction D3 while surrounding the second preliminary semiconductor patterns 170 and the gate insulating pattern layers 220.

The first sacrificial insulating pattern 176 may be formed conformally. In other words, the first sacrificial insulating pattern 176 may be formed with a substantially uniform thickness.

For example, the first sacrificial insulating pattern 176 may be formed by a deposition process, such as a PVD (Physical Vapor Deposition), CVD (Chemical Vapor Deposition), or ALD (Atomic Layer Deposition) process.

The first sacrificial insulating pattern 176 may include an insulating material, for example, may include silicon nitride.

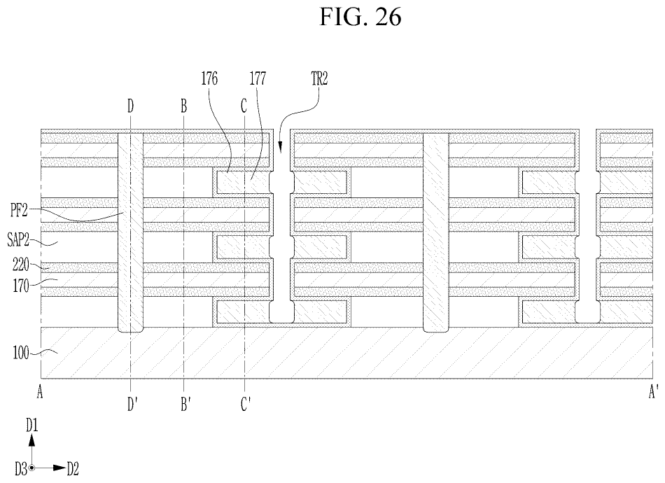

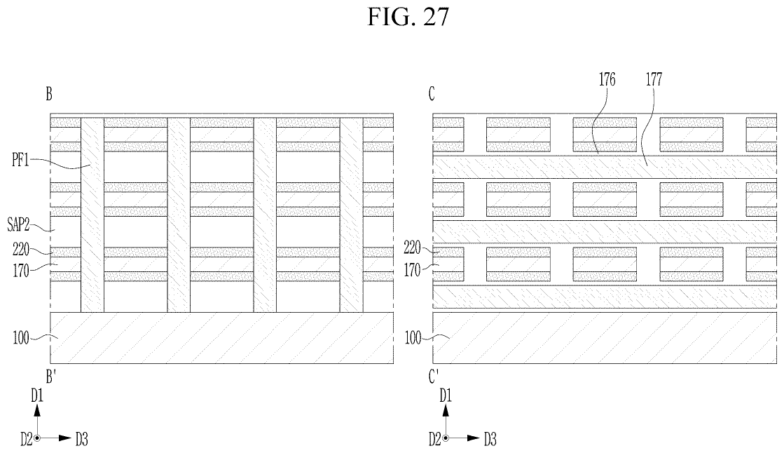

FIG. 26 is a cross-sectional view taken along line A-A′ of FIG. 1, corresponding to FIG. 2. FIG. 27 is a cross-sectional view taken along lines B-B′ and C-C′ of FIG. 1, corresponding to FIG. 3.

Referring to FIGS. 26 and 27, after forming the first sacrificial insulating pattern 176, the second sacrificial insulating pattern 177 may be formed on the first sacrificial insulating pattern 176. The second sacrificial insulating pattern 177 may fill the first inner regions INR1 where the first sacrificial insulating pattern 176 is formed.

The second sacrificial insulating pattern 177 may extend in a third direction D3. In some regions, the first sacrificial insulating pattern 176 and the second sacrificial insulating pattern 177 may be alternately arranged in the first direction D1.

For example, forming the second sacrificial insulating pattern 177 may include depositing a second sacrificial insulating layer that fills the first inner regions INR1 on the first sacrificial insulating pattern 176, and removing the second sacrificial insulating layer formed on the other side in the second direction D2 of the second preliminary semiconductor patterns 170 and the gate insulating pattern layers 220. The remaining second sacrificial insulating layer after removal may constitute the second sacrificial insulating pattern 177.

For example, the second sacrificial insulating layer may be formed by a deposition process, such as PVD (Physical Vapor Deposition), CVD (Chemical Vapor Deposition), or ALD (Atomic Layer Deposition) processes. Additionally, the second sacrificial insulating layer may be removed through a selective etching process or a cleaning process.

The second sacrificial insulating pattern 177 may include an insulating material, for example, may include silicon oxide.

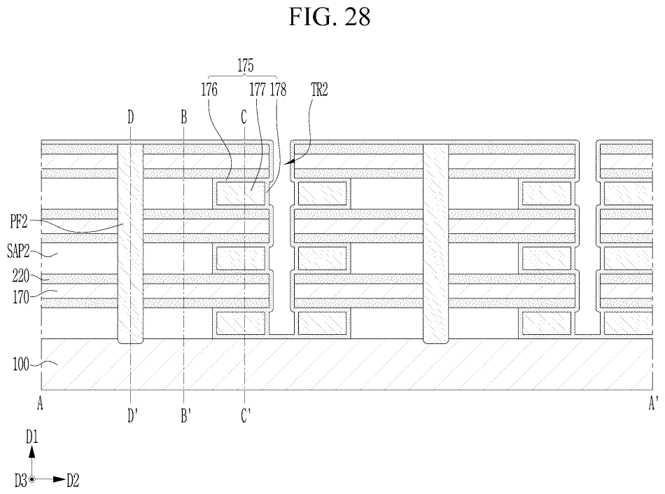

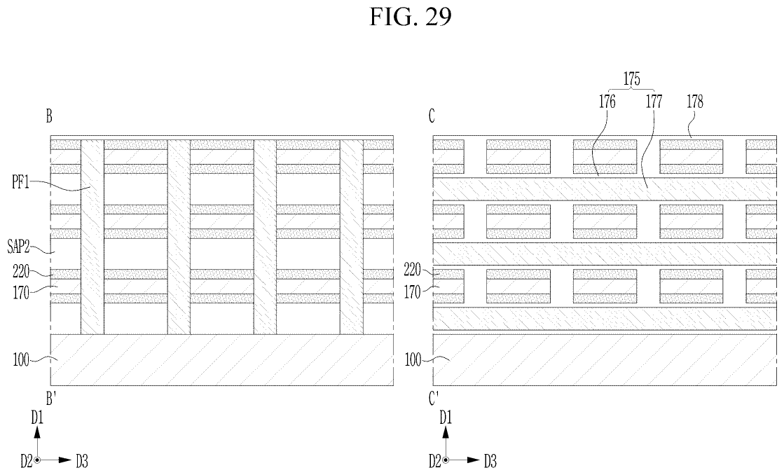

FIG. 28 is a cross-sectional view taken along line A-A′ of FIG. 1, corresponding to FIG. 2. FIG. 29 is a cross-sectional view taken along lines B-B′ and C-C′ of FIG. 1, corresponding to FIG. 3.

Referring to FIGS. 28 and 29, a third sacrificial insulating pattern 178 may be formed on the first sacrificial insulating pattern 176 and the second sacrificial insulating pattern 177 to form a sacrificial insulating structure 175.

For example, the third sacrificial insulating pattern 178 may be formed on the first sacrificial insulating pattern 176 positioned on the other side in the second direction D2 of the second preliminary semiconductor patterns 170 and the other side in the second direction D2 of the gate insulating pattern layer 220. The third sacrificial insulating pattern 178 may be formed on the second sacrificial insulating pattern 177. Additionally, the third sacrificial insulating pattern 178 may be formed on the first sacrificial insulating pattern 176 positioned on the upper surface of the substrate 100.

The third sacrificial insulating pattern 178 may be formed conformally. In other words, the third sacrificial insulating pattern 178 may be formed with a substantially uniform thickness.

For example, the third sacrificial insulating pattern 178 may be formed by a deposition process, such as a Physical Vapor Deposition (PVD), Chemical Vapor Deposition (CVD), or Atomic Layer Deposition (ALD) process.

The third sacrificial insulating pattern 178 may include an insulating material, for example, may include silicon nitride.

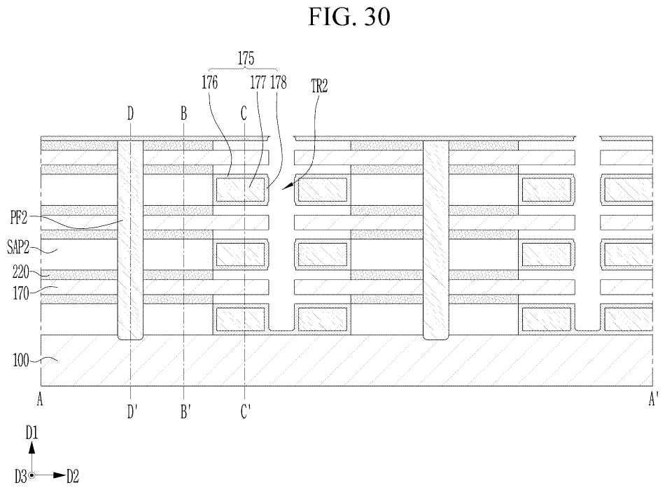

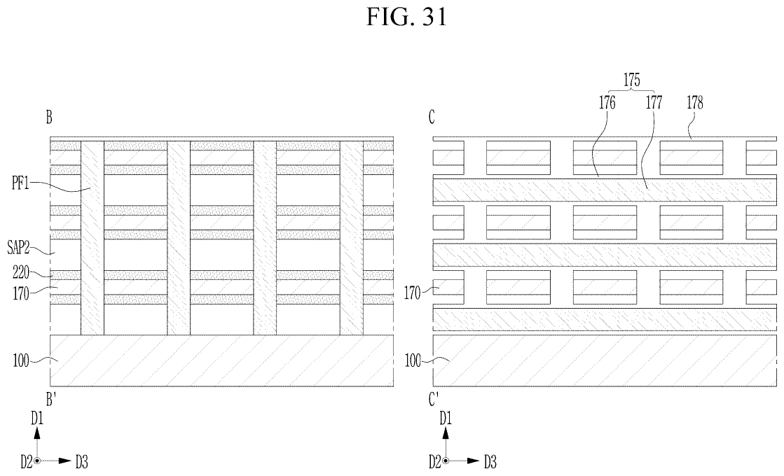

FIG. 30 is a cross-sectional view taken along the line A-A′ of FIG. 1, corresponding to FIG. 2. FIG. 31 is a cross-sectional view taken along the line B-B′ and C-C′ of FIG. 1, corresponding to FIG. 3.

Referring to FIGS. 30 and 31, the other side in the second direction D2 of the gate insulating pattern layers 220 may be selectively removed through a selective etching process.

For example, removing the gate insulating pattern layers 220 may include removing the first sacrificial insulating pattern 176 and the third sacrificial insulating pattern 178 positioned on the other side in the second direction D2 of the gate insulating pattern layers 220, exposing the other side in the second direction D2 of the gate insulating pattern layers 220, and selectively etching the exposed other side in the second direction D2 of the gate insulating pattern layers 220.

For example, selectively removing the other side in the second direction D2 of the gate insulating pattern layers 220 may use a selective etching process such as wet etching or dry etching, and the selective etching process of the gate insulating pattern layers 220 may be a time etch performed for an appropriate period.

As the other side in the second direction D2 of the gate insulating pattern layers 220 is selectively removed, a portion of the other side of the second preliminary semiconductor patterns 170 in the second direction D2 and both sides in the first direction D1 may be exposed.

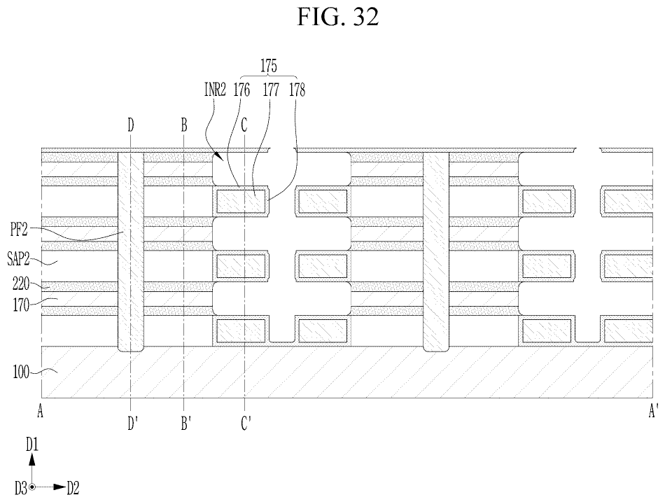

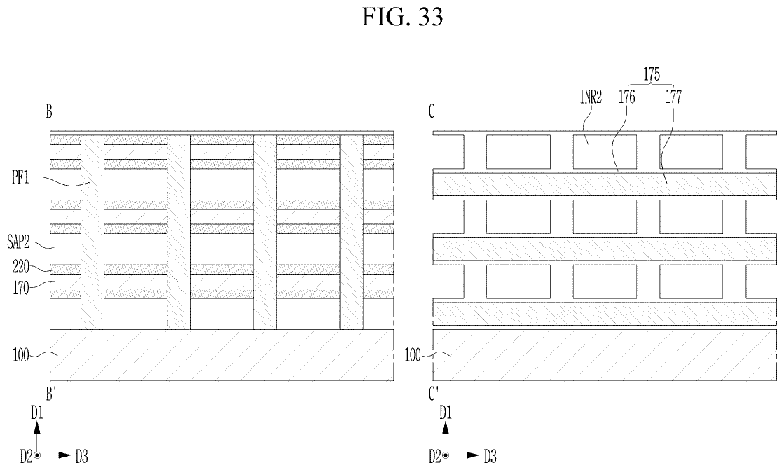

FIG. 32 is a cross-sectional view taken along the A-A′ line of FIG. 1, corresponding to FIG. 2. FIG. 33 is a cross-sectional view taken along the B-B′ line and C-C′ line of FIG. 1, corresponding to FIG. 3.

Referring to FIGS. 32 and 33, as the gate insulating pattern layers 220 are removed, the other side in the second direction D2 of the second preliminary semiconductor patterns 170 that are exposed may be removed through a selective etching process.

The other side in the second direction D2 of the second preliminary semiconductor patterns 170 may be aligned with the other side in the second direction D2 of the gate insulating pattern layers 220. By this, the other side in the second direction D2 of the second preliminary semiconductor patterns 170 and the other side in the second direction D2 of the gate insulating pattern layers 220 may form a coplanar surface.

One side in the second direction D2 of the second preliminary semiconductor patterns 170 may be selectively removed, and the second inner regions INR2 may be formed between the second sacrificial insulating patterns 177 neighboring in the first direction D1. Additionally, the second inner regions INR2 may be positioned spaced apart in the third direction D3 by the first sacrificial insulating patterns 176. In other words, the second inner regions INR2 may be empty spaces surrounded by the first sacrificial insulating patterns 176 and the second sacrificial insulating patterns 177.

For example, selectively removing one side in a second direction D2 of the second preliminary semiconductor patterns 170 may use a selective etching process such as wet etching or dry etching, and the selective etching process of the second preliminary semiconductor patterns 170 may be a time etch performed for an appropriate period.

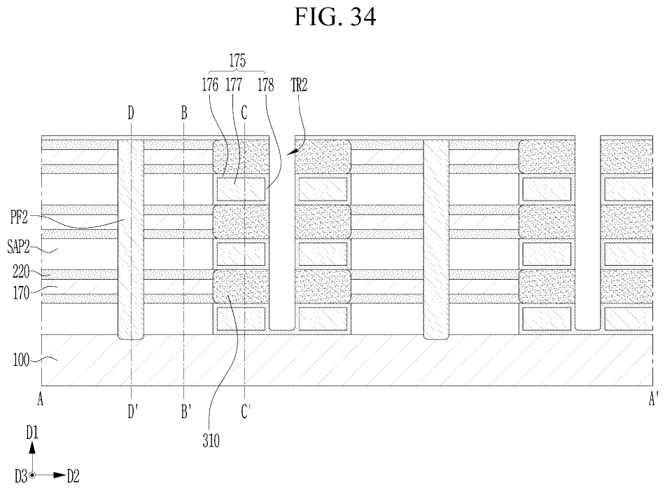

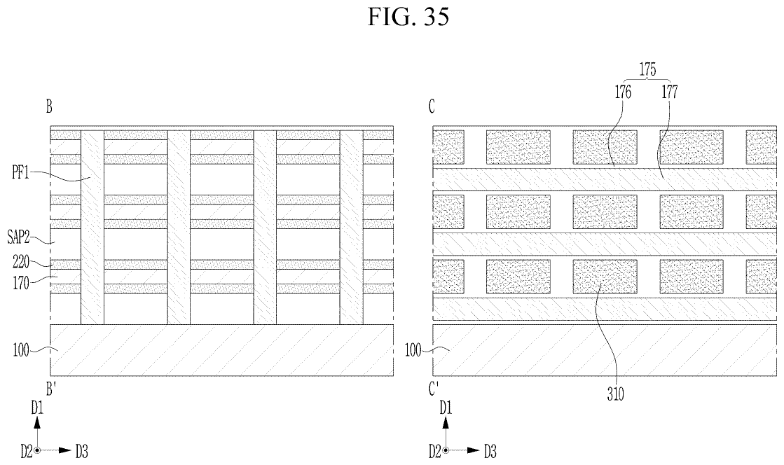

FIG. 34 is a cross-sectional view taken along line A-A′ of FIG. 1, corresponding to FIG. 2. FIG. 35 is a cross-sectional view taken along lines B-B′ and C-C′ of FIG. 1, corresponding to FIG. 3.

Referring to FIGS. 34 and 35, a first electrode 310 of the data storage pattern DS may be formed within the second inner regions INR2. The first electrode 310 may be formed within the second inner regions INR2, which are surrounded by the first sacrificial insulating patterns 176 and the second sacrificial insulating patterns 177 on one side of the second preliminary semiconductor pattern 170 in the second direction D2. For example, the first electrode 310 may be formed to fill the empty space within the second inner regions INR2.

In some embodiments, the first electrode 310 may be formed in the shape of a thin film having a uniform thickness following the surface shape within the second inner regions INR2. Accordingly, the first electrode 310 may have a cylindrical shape with an empty inner space.

For example, the first electrode 310 may be deposited by an Atomic Layer Deposition process, but is not limited thereto.

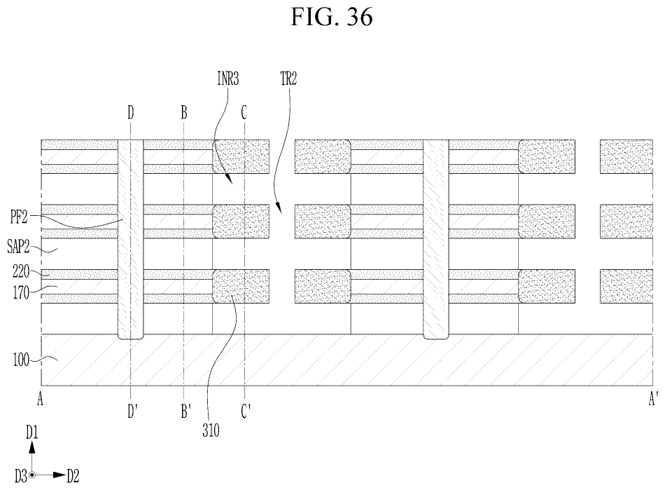

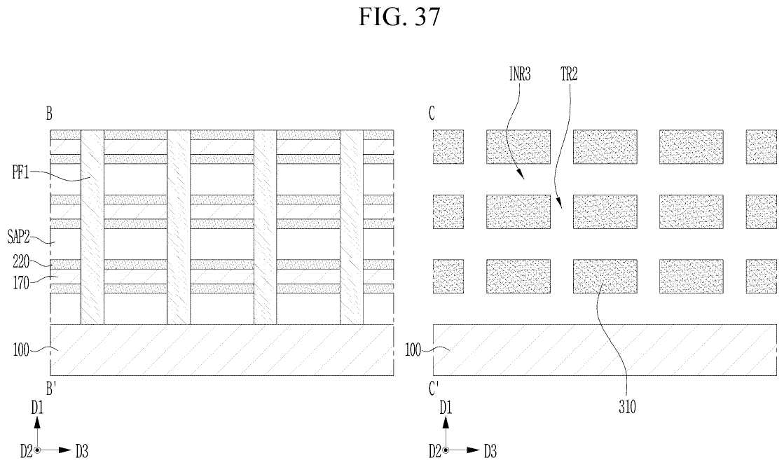

FIG. 36 is a cross-sectional view taken along line A-A′ of FIG. 1 and corresponds to FIG. 2. FIG. 37 is a cross-sectional view taken along line B-B′ and line C-C′ of FIG. 1 and corresponds to FIG. 3.

Referring to FIGS. 36 and 37, the first sacrificial insulating patterns 176 and the second sacrificial insulating patterns 177 are removed.

For example, the first sacrificial insulating patterns 176 and the second sacrificial insulating patterns 177 may be removed through a selective etching process. Through the removal of the first sacrificial insulating patterns 176 and the second sacrificial insulating patterns 177, the surfaces on both sides in the first direction D1 of the first electrode 310 may be exposed.

The other side in the second direction D2 of the second sacrificial patterns SAP2 may be aligned with the other side in the second direction D2 of the second preliminary semiconductor pattern 170 and the other side in the second direction D2 of the gate insulating pattern layer 220. Thereby, the other side in the second direction D2 of the second sacrificial patterns SAP2, the other side in the second direction D2 of the second preliminary semiconductor pattern 170, and the other side in the second direction D2 of the gate insulating pattern layer 220 may form a coplanar surface.

The first sacrificial insulating patterns 176 and the second sacrificial insulating patterns 177 are removed, and the third inner regions INR3 may be formed between the first electrodes 310 adjacent in the first direction D1. Additionally, the third inner regions INR3 may overlap with the second trenches TR2 and extend in the third direction D3.

For example, selectively removing the first sacrificial insulating patterns 176 and the second sacrificial insulating patterns 177 may use a selective etching process such as wet etching or dry etching, and the selective etching process of the first sacrificial insulating patterns 176 and the second sacrificial insulating patterns 177 may be a time etch performed for an appropriate period.

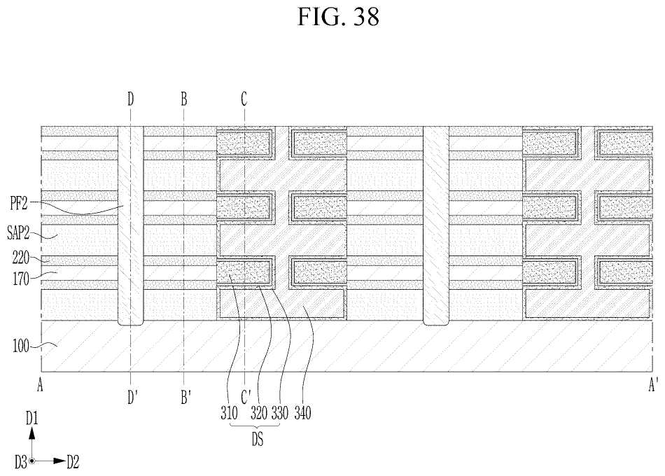

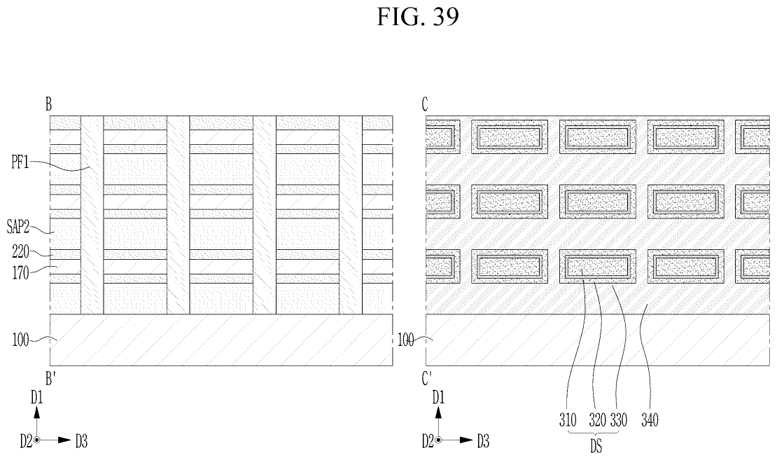

FIG. 38 is a cross-sectional view taken along line A-A′ of FIG. 1, corresponding to FIG. 2. FIG. 39 is a cross-sectional view taken along line B-B′ of FIG. 1, corresponding to FIG. 3.

Referring to FIGS. 38 and 39, the data storage pattern DS may be formed by sequentially stacking a dielectric layer 320 and a second electrode 330 on the surface of the first electrode 310.

First, the dielectric layer 320 is formed on the surface of the first electrode 310.

The dielectric layer 320 may be formed on the outer surface of the first electrode 310. For example, the dielectric layer 320 may be formed on the outer surface of the first electrode 310 exposed by the third inner regions INR3 and the second trenches TR2.

The dielectric layer 320 may be conformally formed on the first electrode 310. In other words, the dielectric layer 320 may be formed as a thin film having a uniform thickness along the surface shape of the first electrode 310.

For example, the dielectric layer 320 may be deposited by an Atomic Layer Deposition (ALD) process, but is not limited thereto.

In some embodiments, when the first electrode 310 has a cylindrical shape, the dielectric layer 320 may be formed on the inner surface and outer surface of the first electrode 310. Additionally, the dielectric layer 320 may be formed on one surface of the second sacrificial patterns SAP2 positioned in a second direction D2 between the first electrodes 310, which are spaced apart in the first direction D1.

Next, the second electrode 330 is formed on the dielectric layer 320.

The second electrode 330 may be formed on the dielectric layer 320. For example, the second electrode 330 may be formed spaced apart from the first electrode 310 with the dielectric layer 320 interposed therebetween.

Further, the second electrode 330 may also be formed on the other surface in the second direction D2 of the second sacrificial patterns SAP2 positioned between the first electrodes 310 spaced apart in the first direction D1.

The second electrode 330 may be formed conformally on the dielectric layer 320. In other words, the second electrode 330 may be formed as a thin film having a uniform thickness along the surface shape of the first electrode 310.

For example, the second electrode 330 may be deposited by a Physical Vapor Deposition (PVD) or Chemical Vapor Deposition (CVD) process, but is not limited thereto.

In some embodiments, when the first electrode 310 has a cylindrical shape, the second electrode 330 may be formed on the inner surface and outer surface of the first electrode 310. Furthermore, the second electrode 330 may be formed to fill the third inner regions INR3 and the second trenches TR2 instead of being conformally formed. In other words, the second electrode 330 may be formed instead of the second spacer 340 described later.

Next, a second spacer 340 is formed on the second electrode 330.

The second spacer 340 may be formed to fill the third inner regions INR3 and the second trenches TR2.

For example, the second electrode 330 may be formed by a Physical Vapor Deposition (PVD) or Chemical Vapor Deposition (CVD) process, but is not limited thereto.

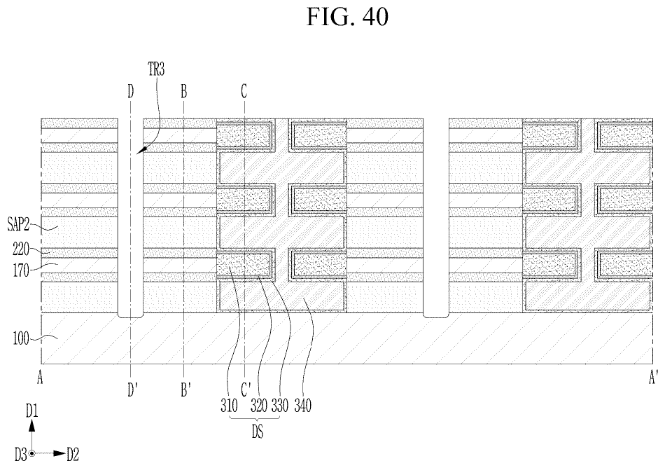

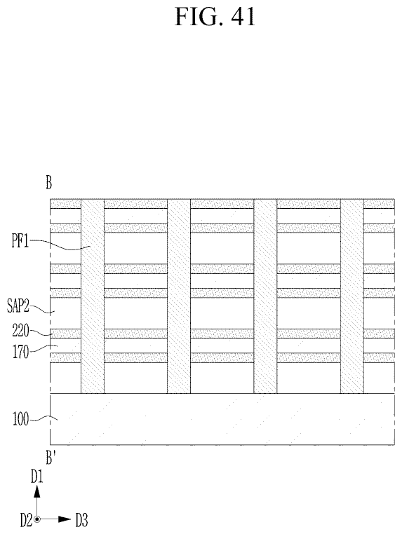

FIG. 40 is a cross-sectional view taken along line A-A′ of FIG. 1, corresponding to FIG. 2. FIG. 41 is a cross-sectional view taken along line B-B′ of FIG. 1, corresponding to FIG. 3.

Referring to FIGS. 40 and 41, the remaining portions of the second preliminary filling patterns PF2 may be removed. For example, the second preliminary filling patterns PF2 positioned in the region where the bit lines BL to be formed may be removed.

The removal of the second preliminary filling patterns PF2 may be achieved by exposing the second preliminary filling patterns PF2 to be removed using a photoresist process, and then removing them through a wet or dry etching process.

As the second preliminary filling patterns PF2 are removed, third trenches TR3 may be formed. The third trenches TR3 may be formed on one side of the second sacrificial patterns SAP2, the second preliminary semiconductor patterns 170, and the gate insulating pattern layers 220 in the second direction D2.

By the third trenches TR3, one side in the second direction D2 of the second sacrificial patterns SAP2, the second preliminary semiconductor patterns 170, and the gate insulating pattern layer 220 may be exposed to the outside. By the third trench TR3, a portion of the upper surface of the substrate 100 may be exposed to the outside.

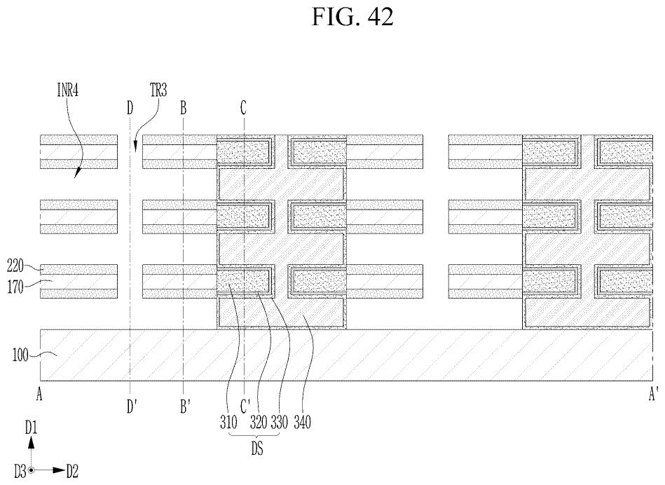

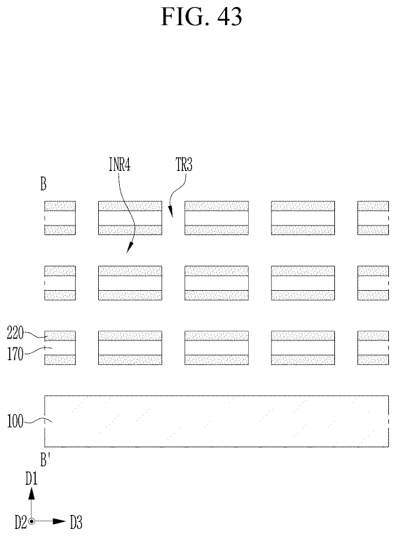

FIG. 42 is a cross-sectional view taken along the line A-A′ of FIG. 1, corresponding to FIG. 2. FIG. 43 is a cross-sectional view taken along the line B-B′ of FIG. 1, corresponding to FIG. 3.

Referring to FIGS. 42 and 43, the second sacrificial patterns SAP2 exposed by the third trench TR3 may be selectively removed through a selective etching process. At this time, the second sacrificial patterns SAP2 may be entirely removed.

The second sacrificial patterns SAP2 are selectively removed, and the fourth inner regions INR4 may be formed between the second preliminary semiconductor patterns 170 adjacent in the first direction D1. The one side in the second direction D2 of the second electrode 330 of the data storage pattern DS may be exposed by the fourth inner regions INR4.

For example, the second sacrificial patterns SAP2 exposed by the third trench TR3 may be removed through a selective etching process, such as wet etching or dry etching.

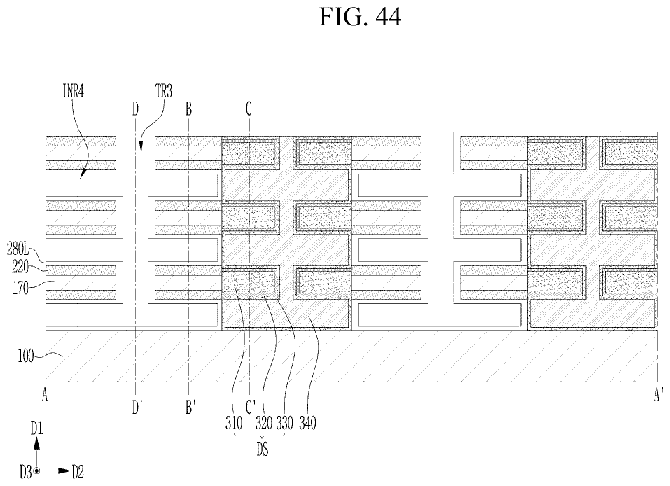

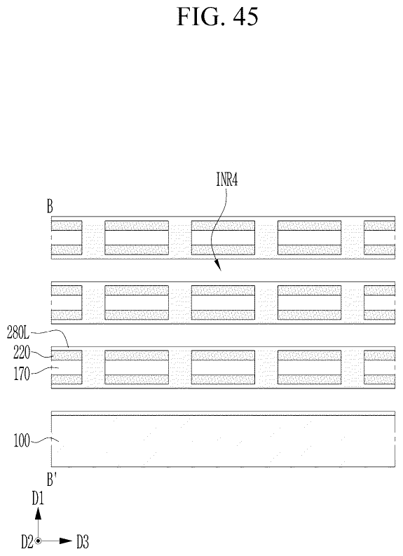

FIG. 44 is a cross-sectional view taken along line A-A′ of FIG. 1, corresponding to FIG. 2. FIG. 45 is a cross-sectional view taken along line B-B′ of FIG. 1, corresponding to FIG. 3.

Referring to FIGS. 44 and 45, a gate insulating liner material layer 280L may be formed on one side in the second direction D2 of the second preliminary semiconductor patterns 170 that are exposed by removing the second sacrificial patterns SAP2, and on one side in the second direction D2 and one side in the first direction D1 of the gate insulating pattern layers 220. In addition, the gate insulating liner material layer 280L may be formed on one side in the second direction D2 of the second electrode 330 of the data storage pattern DS exposed by the fourth inner regions INR4, and the gate insulating liner material layer 280L may also be formed on the upper surface of the substrate 100 exposed by the third trench TR3 and the fourth inner regions INR4.

For example, the gate insulating liner material layer 280L may extend in a third direction D3. The gate insulating liner material layer 280L may surround the second preliminary semiconductor patterns 170 and the gate insulating pattern layers 220 while extending in the third direction D3.

The gate insulating liner material layer 280L may be formed conformally. In other words, the gate insulating liner material layer 280L may be formed with a substantially uniform thickness.

For example, the gate insulating liner material layer 280L may be formed by a deposition process, such as a Physical Vapor Deposition (PVD), Chemical Vapor Deposition (CVD), or Atomic Layer Deposition (ALD) process.

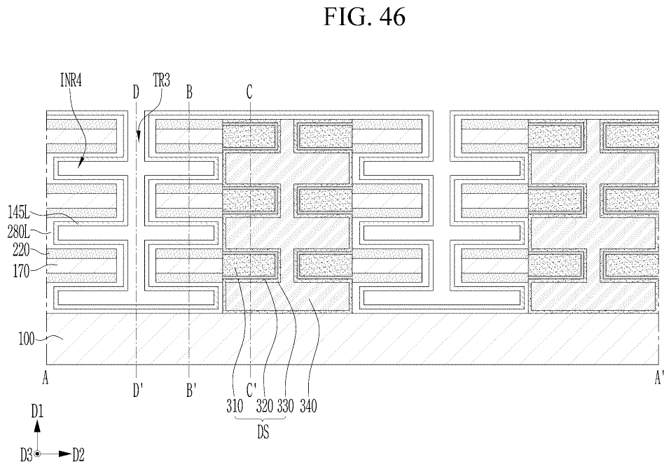

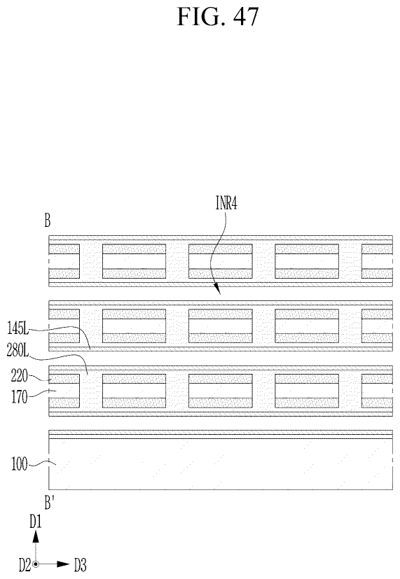

FIG. 46 is a cross-sectional view taken along line A-A′ of FIG. 1, corresponding to FIG. 2. FIG. 47 is a cross-sectional view taken along line B-B′ of FIG. 1, corresponding to FIG. 3.

Referring to FIGS. 46 and 47, a capping material layer 145L may be formed on the gate insulating liner material layer 280L. For example, the capping material layer 145L may be formed on one side in the second direction D2 of the second preliminary semiconductor patterns 170, one side in the second direction D2 and one side in the first direction D1 of the gate insulating pattern layers 220, one side in the second direction D2 of the second electrode 330 of the data storage pattern DS, and on the upper surface of the substrate 100 where the gate insulating liner material layer 280L is positioned.

The capping material layer 145L may be formed conformally. In other words, the capping material layer 145L may be formed with substantially uniform thickness. For example, the capping material layer 145L may extend in the third direction D3.

The capping material layer 145L may include an insulating material, for example, may include silicon nitride.

For example, the capping material layer 145L may be formed by a deposition process, such as a PVD (Physical Vapor Deposition), CVD (Chemical Vapor Deposition), or ALD (Atomic Layer Deposition) process.

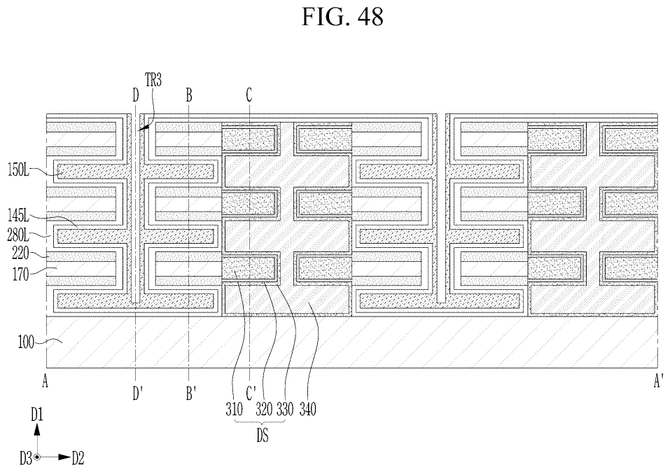

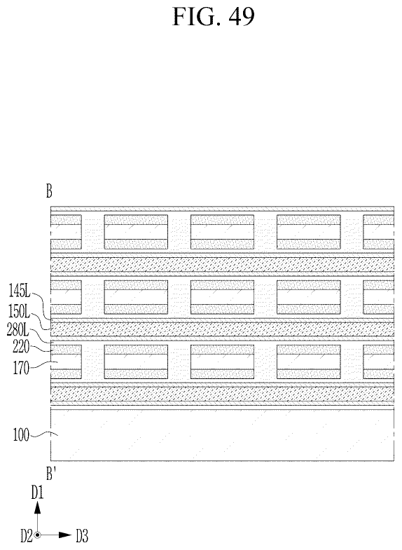

FIG. 48 is a cross-sectional view taken along line A-A′ of FIG. 1, corresponding to FIG. 2. FIG. 49 is a cross-sectional view taken along line B-B′ of FIG. 1, corresponding to FIG. 3.

Referring to FIGS. 48 and 49, after forming the capping material layer 145L, a word line separation material layer 150L may be formed on the capping material layer 145L. The word line separation material layer 150L may fill the fourth inner regions INR4 where the gate insulating liner material layer 280L and the capping material layer 145L are formed.

For example, the word line separation material layer 150L may extend in the third direction D3. In some regions, the gate insulating liner material layer 280L and the word line separation material layer 150L may be alternately arranged in the first direction D1 with the capping material layer 145L interposed therebetween.

For example, the word line separation material layer 150L may be formed by a deposition process, such as a Physical Vapor Deposition (PVD), Chemical Vapor Deposition (CVD), or Atomic Layer Deposition (ALD) process.

The word line separation layer 150L may include an insulating material, for example, may include silicon oxide.

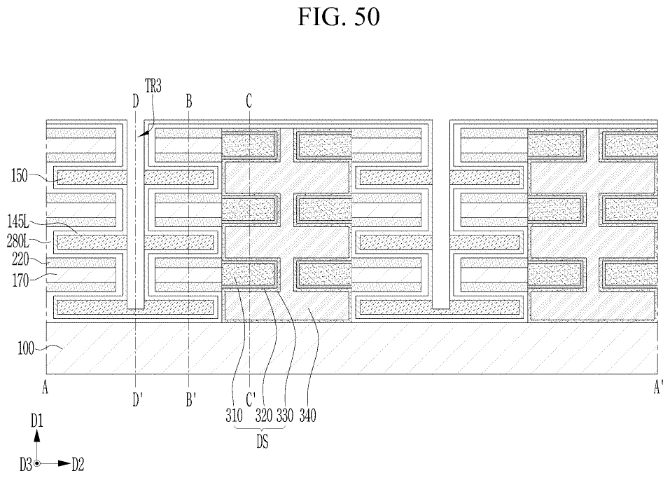

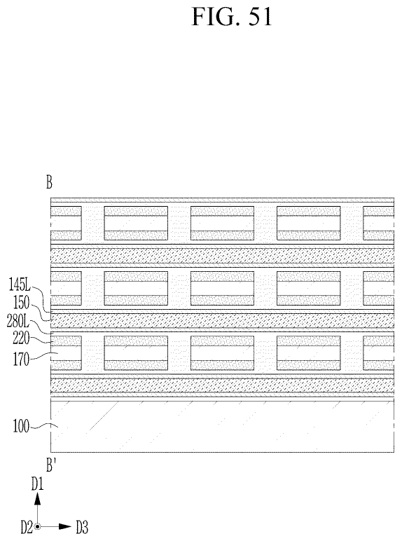

FIG. 50 is a cross-sectional view cut along line A-A′ of FIG. 1, corresponding to FIG. 2. FIG. 51 is a cross-sectional view cut along line B-B′ of FIG. 1, corresponding to FIG. 3.

Referring to FIGS. 50 and 51, the word line separation material layer 150L formed on one side in the second direction D2 of the second preliminary semiconductor patterns 170 and one side in the second direction D2 of the gate insulating pattern layers 220 may be removed. The remaining word line separation material layer 150L after removal may constitute the word line separation layer 150.

For example, the word line separation material layer 150L may be removed through a selective etching process or a cleaning process.

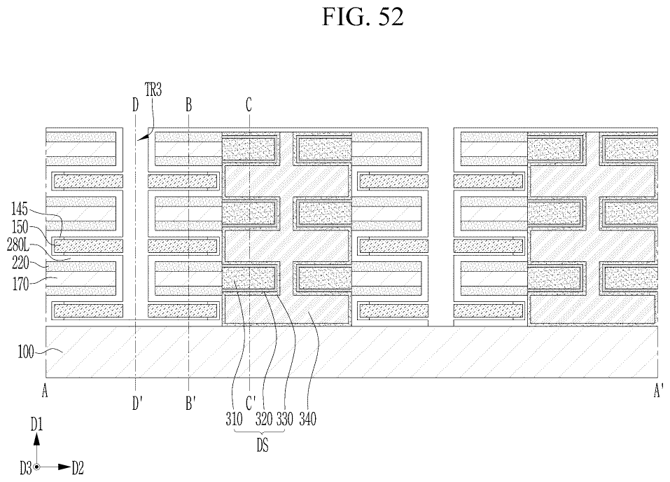

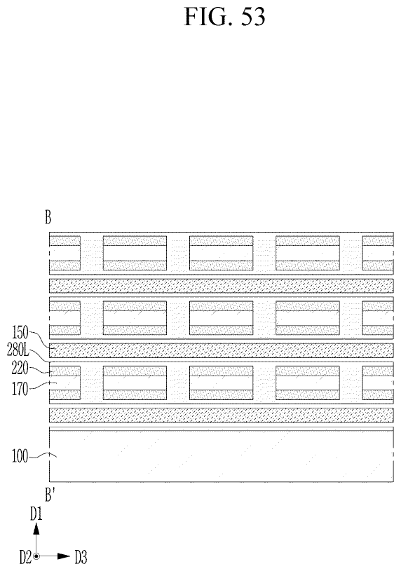

FIG. 52 is a cross-sectional view taken along the A-A′ line of FIG. 1, corresponding to FIG. 2. FIG. 53 is a cross-sectional view taken along the B-B′ line of FIG. 1, corresponding to FIG. 3.

Referring to FIGS. 52 and 53, a portion of the capping material layer 145L may be removed through a selective etching process to form a capping pattern 145.

For example, a portion of the capping material layer 145L positioned on one side in the second direction D2 of the gate insulating pattern layer 220 and one side in the second direction D2 of the second preliminary semiconductor pattern 170 may be removed. Additionally, a portion of the capping material layer 145L positioned between the gate insulating liner material layer 280L and the word line separation layer 150 in the first direction D1 may be removed.

However, a portion of the capping material layer 145L positioned on one side of the second electrode 330 of the data storage pattern DS in the second direction D2 may remain and not be removed, forming the capping pattern 145. The capping pattern 145 may be surrounded by the gate insulating liner material layer 280L and may include a portion positioned between the word line separation layer 150 and the gate insulating pattern layer 220 in the first direction D1 and a portion facing the data storage pattern DS in the second direction D2.

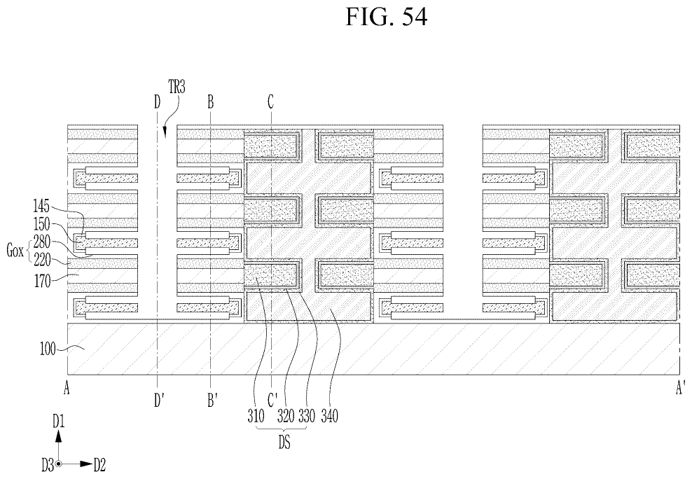

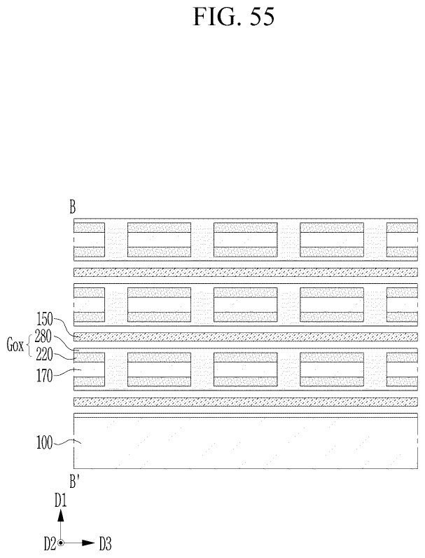

FIG. 54 is a cross-sectional view taken along the A-A′ line of FIG. 1 and corresponds to FIG. 2. FIG. 55 is a cross-sectional view taken along the B-B′ line of FIG. 1 and corresponds to FIG. 3.

Referring to FIGS. 54 and 55, a portion on one side in the second direction D2 of the gate insulating pattern layer 220 and one side in the second direction D2 of the second preliminary semiconductor patterns 170 of the gate insulating liner material layer 280L may be removed. The remaining gate insulating liner material layer 280L after removal may constitute the gate insulating liner 280.

At this time, a portion on one side in the first direction D1 of the gate insulating pattern layer 220 and a portion facing the gate insulating liner material layer 280L of the word line separation layer 150 of the gate insulating liner material layer 280L may be partially removed, thereby reducing length in the first direction D1 of the gate insulating liner material layer 280L and the word line separation layer 150. Accordingly, a length in the first direction D1 of the empty space between the gate insulating liner 280 and the word line separation layer 150 may increase, and space for forming a word line WL between the gate insulating liner 280 and the word line separation layer 150 may be secured. FIGS. 52 and 54 illustrate a portion of each of the gate insulating liner material layer 280L and the word line separation layer 150 is removed, but is not limited thereto. For example, the space may be secured by partially removing a selected one of the gate insulating liner material layer 280L and the word line separation layer 150.

The gate insulating liner material layer 280L may be removed through a selective etching process or cleaning process.

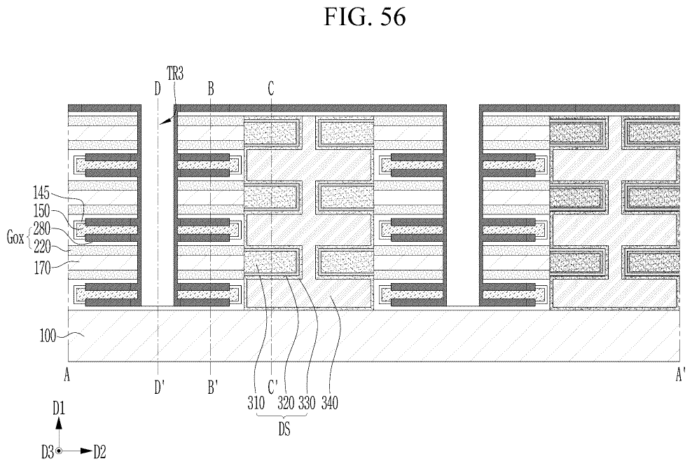

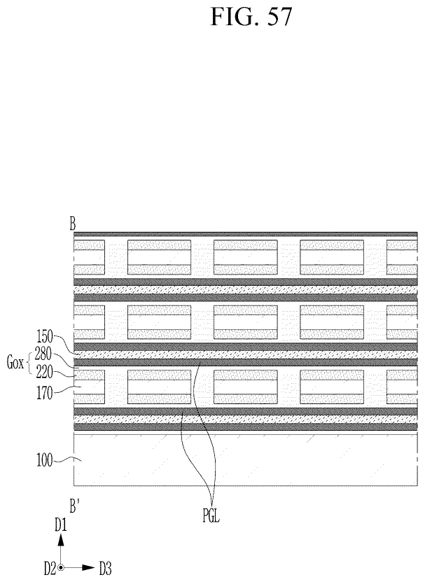

FIG. 56 is a cross-sectional view taken along line A-A′ of FIG. 1 and corresponds to FIG. 2. FIG. 57 is a cross-sectional view taken along line B-B′ of FIG. 1 and corresponds to FIG. 3.

Referring to FIGS. 56 and 57, a preliminary gate conductive layer PGL may be formed in the empty space between the gate insulating liner 280 and the word line separation layer 150. The preliminary gate conductive layer PGL may extend in the third direction D3.

Moreover, the preliminary gate conductive layer PGL may be formed on one side in the second direction D2 of the second preliminary semiconductor patterns 170, on one side in the second direction D2 of the gate insulating pattern layers 220, on one side in the second direction D2 of the gate insulating liner 280, and on one side in the second direction D2 of the word line separation layer 150.

The preliminary gate conductive layer PGL may be formed conformally. In other words, the preliminary gate conductive layer PGL may be formed with a substantially uniform thickness.

In some embodiments, when not forming the gate insulating pattern layer 220, the preliminary gate conductive layer PGL may surround the second preliminary semiconductor patterns 170 spaced apart in the third direction D3 and extend in the third direction D3.

For example, the preliminary gate conductive layer PGL may be deposited by an Atomic Layer Deposition (ALD) process, but is not limited thereto.

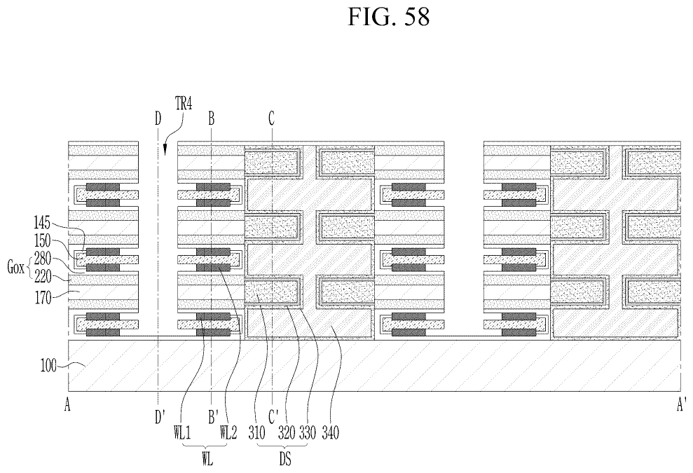

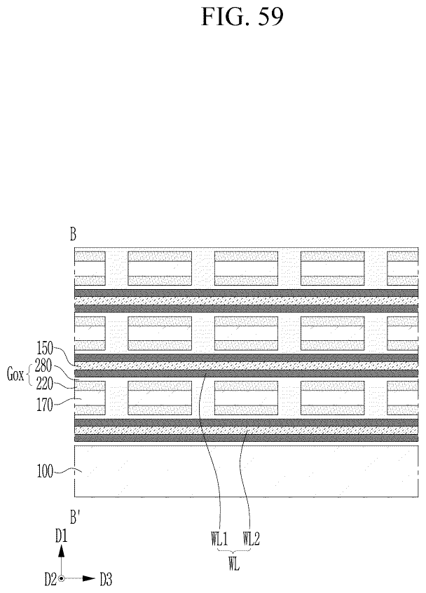

FIG. 58 is a cross-sectional view taken along line A-A′ of FIG. 1, corresponding to FIG. 2. FIG. 59 is a cross-sectional view taken along line B-B′ of FIG. 1, corresponding to FIG. 3.

Referring to FIGS. 58 and 59, a portion of the preliminary gate conductive layer PGL may be removed to form a word line WL.

For example, the preliminary gate conductive layer PGL formed on one side in the second direction D2 of the second preliminary semiconductor patterns 170 and one side in the second direction D2 of the gate insulating pattern layer 220 may be removed. The remaining preliminary gate conductive layer PGL after removal may constitute the word line WL.

At this time, one side in the second direction D2 of the word line WL may be more recessed than one side in the second direction D2 of the word line separation layer 150, and as described later, a first spacer 140 may be formed in the recessed space of the word line WL.

The preliminary gate conductive layer PGL may be removed through a selective etching process or a cleaning process. For example, the etching process may be a wet etching process.

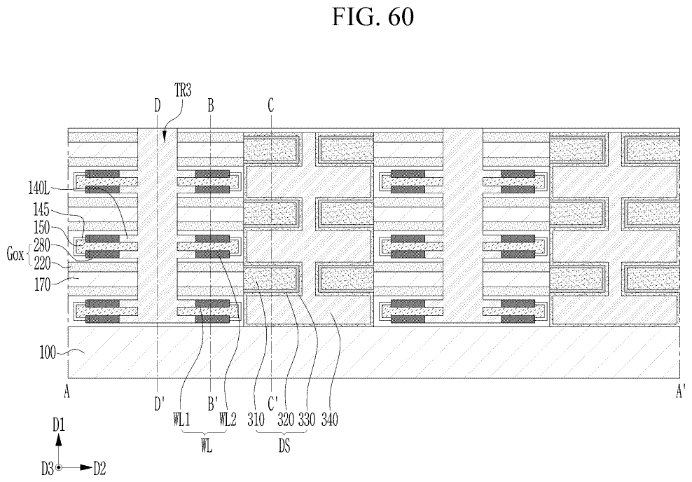

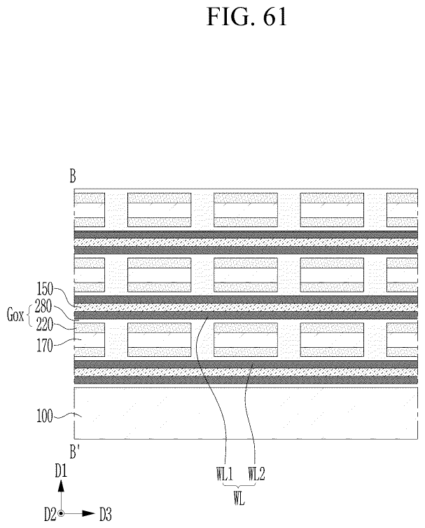

FIG. 60 is a cross-sectional view taken along the A-A′ line of FIG. 1, corresponding to FIG. 2. FIG. 61 is a cross-sectional view taken along the B-B′ line of FIG. 1, corresponding to FIG. 3.

Referring to FIGS. 60 and 61, a buried insulating pattern 140L may be formed on the word line WL.

The buried insulating pattern 140L may be formed in a recessed space on one side of the word line WL in the second direction D2. Additionally, the buried insulating pattern 140L may be formed to fill the third trenches TR3.

For example, the buried insulating pattern 140L may be formed by a Physical Vapor Deposition (PVD) or Chemical Vapor Deposition (CVD) process, but is not limited thereto.

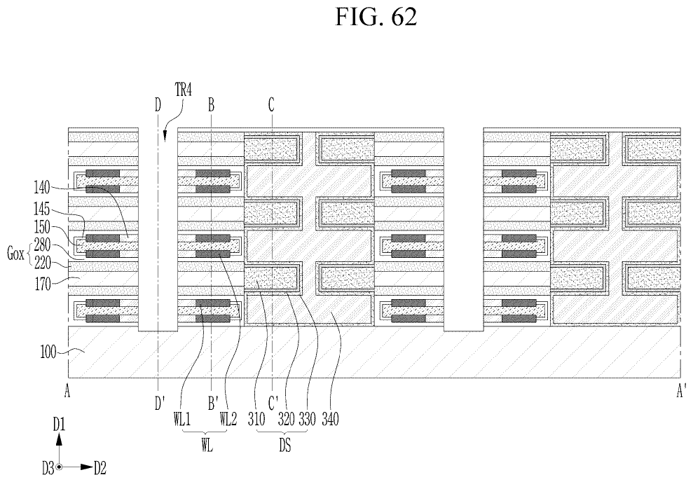

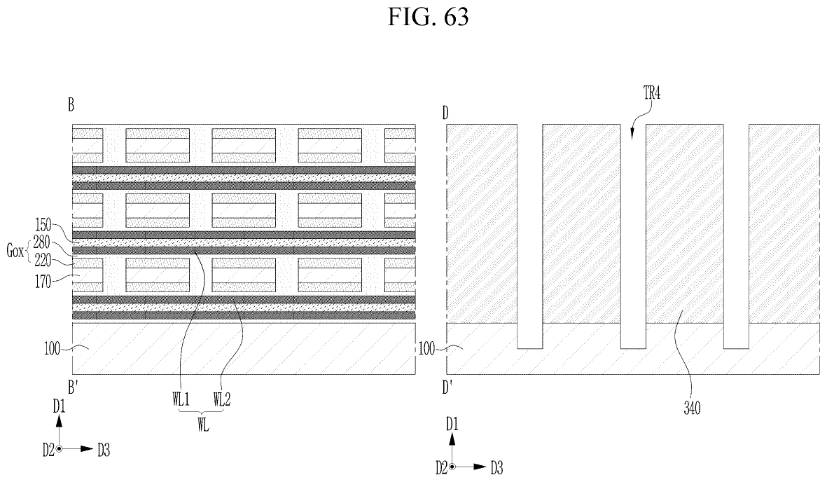

FIG. 62 is a cross-sectional view taken along the A-A′ line of FIG. 1, corresponding to FIG. 2. FIG. 63 is a cross-sectional view taken along the B-B′ line and D-D′ line of FIG. 1, corresponding to FIGS. 3 and 4.

Referring to FIGS. 62 and 63, portions of the buried insulating patterns 140L may be removed. For example, some portions of the buried insulating patterns 140L, which are positioned in the region where the bit lines BL will be formed, may be removed.

However, the buried insulating patterns 140L formed on one side of the recess region in the second direction D2 of the word line WL may not be removed. The remaining buried insulating patterns 140L that are not removed may constitute the first spacers 140.

Additionally, the buried insulating patterns 140L positioned between bit lines BL, which are to be formed spaced apart in the third direction D3, may not be removed. The remaining buried insulating patterns 140L that are not removed may constitute bit line spacers 300.

As portions of the buried insulating patterns 140L are removed, fourth trenches TR4 may be formed. The fourth trenches TR4 may be formed on one side in the second direction D2 of the second preliminary semiconductor patterns 170, the gate insulating pattern layers 220, the gate insulating liners 280, the word lines WL, and the word line separating layers 150.

By the fourth trenches TR4, one side in the second direction D2 of the second preliminary semiconductor patterns 170, the gate insulating pattern layers 220, the gate insulating liners 280, the first spacers 140, and the word line separation layers 150 may be exposed to the outside. Additionally, by the fourth trenches TR4, one side in the second direction D2 of the second preliminary semiconductor patterns 170, the gate insulating pattern layers 220, the gate insulating liners 280, the first spacers 140, and the word line separation layers 150 may be aligned in the first direction D1. By the fourth trenches TR4, some portions of the upper surface of the substrate 100 may be exposed to the outside.

During the formation process of the fourth trenches TR4, a portion of the buried insulating patterns 140L may be removed using a photoresist process. For example, after forming a mask pattern that exposes a portion of the buried insulating patterns 140L on the structures shown in FIGS. 60 and 61, the exposed portion of the buried insulating patterns 140L may be removed using a wet and/or dry etching process.

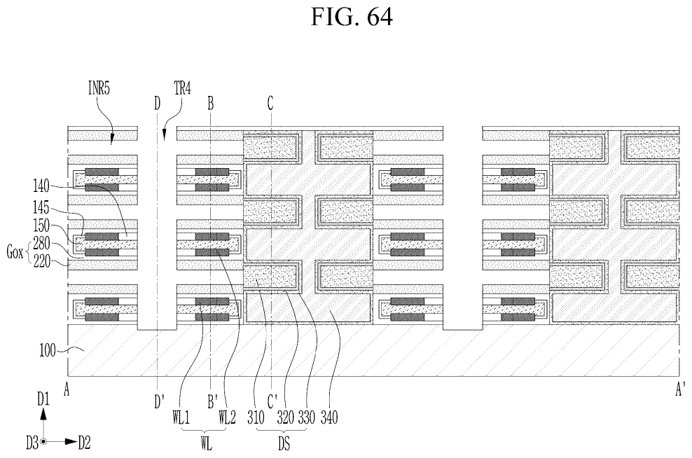

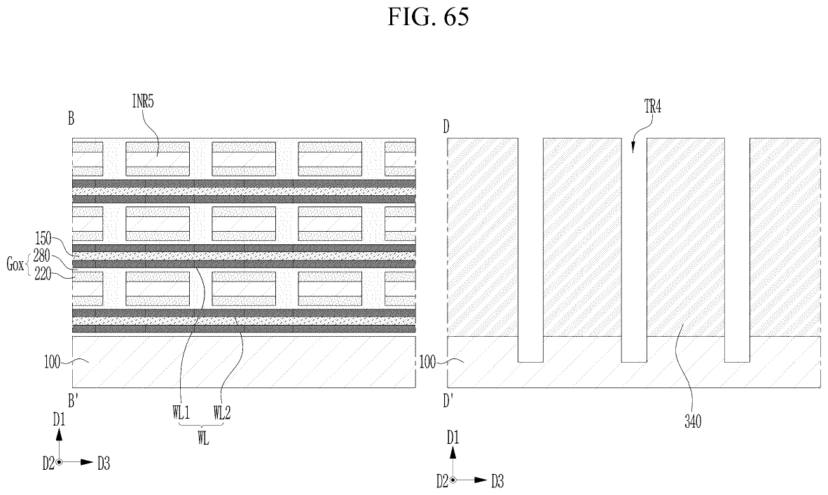

FIG. 64 is a cross-sectional view taken along the line A-A′ of FIG. 1, corresponding to FIG. 2. FIG. 65 is a cross-sectional view taken along the lines B-B′ and D-D′ of FIG. 1, corresponding to FIGS. 3 and 4.

Referring to FIGS. 64 and 65, the second preliminary semiconductor patterns 170 exposed by the fourth trench TR4 may be removed through a selective etching process. At this time, the second preliminary semiconductor patterns 170 may be entirely removed.

The second preliminary semiconductor patterns 170 may be selectively removed to form fifth inner regions INR5 between the gate insulating pattern layers 220 neighboring in the first direction D1. Additionally, the fifth inner regions INR5 may be spaced apart from each other in the third direction D3 by the gate insulating liners 280. In other words, the fifth inner regions INR5 may be empty spaces surrounded by the gate insulating pattern layers 220 and the gate insulating liners 280.

For example, selectively removing one side in the second direction D2 of the second preliminary semiconductor patterns 170 may use a selective etching process such as wet etching or dry etching. For example, the etching process may include chemical etching using an etching selectivity among components. In another example, the etching process for the selective etching of the second preliminary semiconductor patterns 170 may include a time etch performed for an appropriate period.

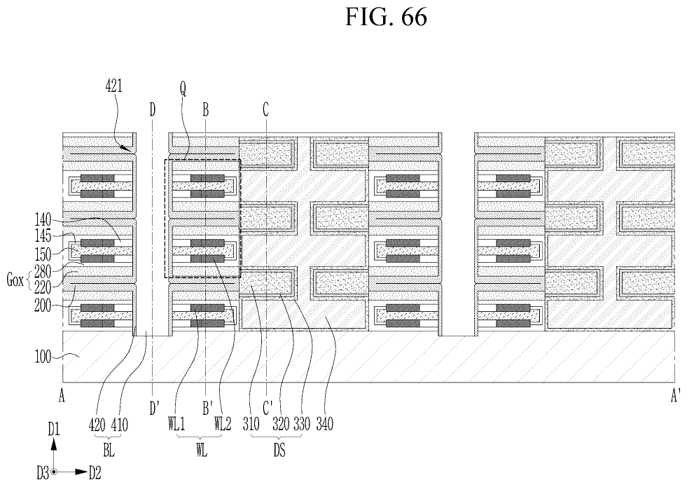

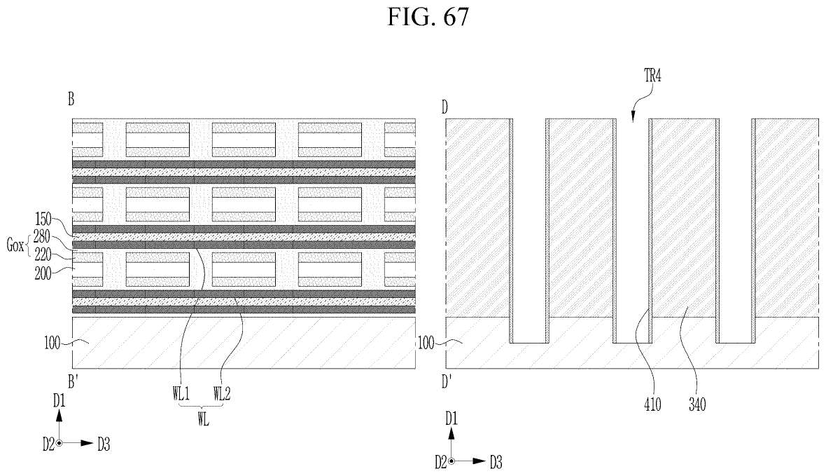

FIG. 66 is a cross-sectional view taken along the line A-A′ of FIG. 1, corresponding to FIG. 2. FIG. 67 is a cross-sectional view taken along the lines B-B′ and D-D′ of FIG. 1, corresponding to FIGS. 3 and 4.

Referring to FIGS. 66 and 67, a semiconductor pattern 200 and a first oxide semiconductor layer 420 may be formed.

For example, the semiconductor patterns 200 may be formed within the fifth inner regions INR5. The semiconductor patterns 200 may be formed within the fifth inner regions INR5 surrounded by the gate insulating pattern layers 220 and the gate insulating liners 280 on one side in the second direction D2 of the first electrodes 310 of the data storage patterns DS. For example, the semiconductor patterns 200 may be formed to fill the empty space within the fifth inner regions INR5. For example, the semiconductor patterns 200 may be deposited by an Atomic Layer Deposition (ALD) process through the fourth trenches TR4.

For example, the first oxide semiconductor layer 420 may be formed together with the semiconductor patterns 200. For example, by depositing oxide semiconductor material on the surfaces of the gate insulating pattern layers 220 and the gate insulating liners 280 exposed through the fifth inner region INR5, while simultaneously depositing the oxide semiconductor material on the surfaces of the gate insulating pattern layers 220, the gate insulating liners 280, the first spacers 140, and the word line separating layers 150 exposed through the fourth trench TR4, the semiconductor patterns 200 and the first oxide semiconductor layer 420 may be formed. The semiconductor patterns 200 and the first oxide semiconductor layer 420 may be formed simultaneously by the same process and may be made of the same material, their boundaries may not be distinguishable.

In other words, the first oxide semiconductor layer 420 and the semiconductor patterns 200 may be formed while conformally covering the surface of the space exposed by the fifth inner region INR5 and the fourth trench TR4 with an oxide semiconductor material. The surface exposed as the fourth trench TR4 of the oxide semiconductor material formed on the corner where one side in the second direction D2 of the gate insulating pattern layer 220 meets one side in the first direction D1, which is the part where the first oxide semiconductor layer 420 and the semiconductor patterns 200 are connected, may have a rounded shape in cross-section. Accordingly, as the part where the first oxide semiconductor layer 420 and the semiconductor patterns 200 are connected has a rounded shape in cross-section, the first oxide semiconductor layer 420 may have concave portions 421 positioned corresponding to each of the semiconductor patterns 200. The concave portion 421 may have a size and shape corresponding to the size and shape of the semiconductor pattern 200 in the second direction D2 and the third direction D3.

Also, when forming the semiconductor pattern 200 by filling the fifth inner region INR5 with the oxide semiconductor material, the oxide semiconductor material simultaneously may grow from the lower surface in the first direction D1 of one gate insulation pattern layer 220 and may from the upper surface in the first direction D1 of the other gate insulation pattern layer 220. As it fills the fifth inner region INR5 meeting at approximately the midpoint in the first direction D1 of the fifth inner region INR5, the semiconductor pattern 200 may have an interface internally. The interface of the semiconductor pattern 200 extends in the second direction D2 and its end may meet the concave portion 421. However, it is not limited to this, as the semiconductor pattern 200 comprises the same material, the interface may not be indistinguishable.

In some embodiments, after forming the first oxide semiconductor layer 420, a portion of the surface exposed to the fourth trench TR4 of the first oxide semiconductor layer 420 may be removed through a cleaning process. For example, the cleaning process may be performed to the extent of removing concave portions 421 of the first oxide semiconductor layer 420. When the concave portions 421 are removed by the cleaning process, a length in the second direction D2 of the first oxide semiconductor layer 420 may decrease, and as shown in FIG. 2, the first oxide semiconductor layer 420 may not have concave portions 421. Meanwhile, if the cleaning process is not conducted, the first oxide semiconductor layer 420 may have concave portions 421, as shown in FIG. 6.

Referring again to FIG. 1 to FIG. 5, within the fourth trenches TR4, the first oxide semiconductor layer 420 is formed, and in the remaining space, a core conductive layer 410 may be formed, thereby forming a bit line BL including the core conductive layer 410 and the first oxide semiconductor layer 420. For example, the core conductive layer 410 may be formed to fill all the inner regions of the fourth trenches TR4 remaining after the first oxide semiconductor layer 420 is formed.

For example, the semiconductor pattern 200 and the first oxide semiconductor layer 420 may be formed by a PVD (Physical Vapor Deposition), CVD (Chemical Vapor Deposition), or ALD (Atomic Layer Deposition) process. The core conductive layer 410 may be deposited by the ALD process, but is not limited thereto.

The above detailed description of embodiments of the present disclosure is not intended to limit the scope of the present disclosure. Rather, various modifications and improvements made by a person of ordinary skill in the art using the basic concepts of the present disclosure as defined in the following claims also fall within the scope of the present disclosure.

What is claimed is:

1. A semiconductor device comprising
a bit line extending in a first direction,
semiconductor patterns spaced apart in the first direction and having one end in a second direction, different from the first direction, connected to the bit line,
a word line extending in a third direction, different from the first and the second directions, and positioned on one side of each of the semiconductor patterns in the first direction, and
data storage patterns connected to another end of each of the semiconductor patterns in the second direction,
wherein the bit line includes a core conductive layer, and a first oxide semiconductor layer positioned between the core conductive layer and the semiconductor patterns and connected to the semiconductor patterns.

2. The semiconductor device of claim 1, wherein:
the semiconductor patterns include an oxide semiconductor material,
the first oxide semiconductor layer includes a same oxide semiconductor material as a material of the semiconductor patterns, and
the first oxide semiconductor layer and the semiconductor patterns constitute a single body.

3. The semiconductor device of claim 1, wherein the first oxide semiconductor layer has a concave portion on the side facing the core conductive layer, and the concave portion is indented with respect to the semiconductor pattern.

4. The semiconductor device of claim 3, wherein the first oxide semiconductor layer has concave portions positioned corresponding to each of the semiconductor patterns, and the concave portion has a size and shape corresponding to a size and shape of the semiconductor pattern.

5. The semiconductor device of claim 3, wherein the core conductive layer has a first convex portion protruding toward the concave portion of the first oxide semiconductor layer.

6. The semiconductor device of claim 1, wherein the bit line further includes a second oxide semiconductor layer between the core conductive layer and the first oxide semiconductor layer.

7. The semiconductor device of claim 6, wherein the second oxide semiconductor layer includes an oxide semiconductor material different from a material of the first oxide semiconductor layer and the semiconductor pattern.

8. The semiconductor device of claim 6, wherein the first oxide semiconductor layer has a concave portion indented with respect to the semiconductor pattern on the side facing the second oxide semiconductor layer, and
the second oxide semiconductor layer has a second convex portion protruding towards the concave portion of the first oxide semiconductor layer.

9. A semiconductor device comprising
a bit line extending in a first direction,
semiconductor patterns spaced apart in the first direction and having one end in a second direction, different from the first direction, connected to the bit line, a word line extending in a third direction, different from the first and second directions, and positioned on one side of each of the semiconductor patterns in the first direction,
a gate insulating layer positioned between the semiconductor pattern and the word line, and including a gate insulating pattern layer positioned on a side of the semiconductor pattern and a gate insulating liner positioned on a side of the word line, and
a data storage pattern connected to another end of the semiconductor pattern in the second direction,
wherein the gate insulating liner has a first insulating liner portion positioned between the word line and the gate insulating pattern layer, and a second insulating liner portion positioned between the word line and the data storage pattern.

10. The semiconductor device of claim 9, wherein the gate insulating pattern layer is positioned on one or both sides in the first direction of the semiconductor pattern, and
the gate insulating liner is positioned on one or both sides in the first direction of the semiconductor pattern, or is positioned on one side in the first direction of the gate insulating pattern layer, and
the gate insulating liner is positioned on both sides in the third direction of the semiconductor pattern, and is positioned on both sides in the third direction of the gate insulating pattern layer.

11. The semiconductor device of claim 9, wherein the gate insulating layer includes the gate insulating pattern layers,
one of the gate insulating pattern layers is positioned on one side of the semiconductor pattern in the first direction,
the other of the gate insulating pattern layer is positioned on another side of the semiconductor pattern in the first direction, and
a length of the gate insulating pattern layer in the third direction is approximately same as a length of the semiconductor pattern in the third direction.

12. The semiconductor device of claim 9, wherein the gate insulating liner further has third insulating liner portions positioned between the semiconductor patterns spaced apart in the third direction, and
the first insulating liner portion and the second insulating liner portion extend long in the third direction passing through the semiconductor patterns.

13. The semiconductor device of claim 12, wherein the gate insulating liner surrounds the semiconductor pattern or a stack including the semiconductor pattern and the gate insulating pattern layer.

14. The semiconductor device of claim 9, wherein the semiconductor device includes first word lines positioned below the first direction of the semiconductor pattern, and second word lines positioned above the first direction semiconductor pattern, and
the first word line positioned below the first direction of one semiconductor pattern and the second word line positioned above the first direction of the other semiconductor pattern below the first direction of the one semiconductor pattern are spaced apart in the first direction.

15. The semiconductor device of claim 14, wherein the semiconductor device further includes a word line separation layer positioned between the first word line and the second word line spaced apart in the first direction, and
the second insulating liner portion is positioned between the data storage pattern and the word line separation layer.

16. The semiconductor device of claim 14, wherein the semiconductor device further includes a capping pattern positioned on one side in the first direction of the semiconductor pattern and positioned between the word line and the data storage pattern in the second direction.

17. The semiconductor device of claim 16, wherein the capping pattern includes a first capping portion positioned between the word line separation layer and the first insulating liner portion of the gate insulating liner in the first direction, and a second capping portion positioned between the word line separation layer and the second insulating liner portion of the gate insulating liner in the second direction.

18. The semiconductor device of claim 17, wherein:
the first capping portion is positioned at one end in the second direction of the first word line of the one semiconductor pattern and at one end in the second direction of the second word line of the other semiconductor pattern, and
the second capping portion connects the first capping portion positioned at one end in the second direction of the first word line and the first capping portion positioned at one end in the second direction of the second word line.

19. The semiconductor device of claim 9, wherein the semiconductor device further includes a first spacer positioned between the word line and the bit line in the second direction.

20. A semiconductor device comprising
a bit line extending in a first direction,
a semiconductor structure having one side in a second direction, different from the first direction, connected to the bit line,
a word line extending in a third direction, different from the first and the second directions, and positioned on one side in the first direction of the semiconductor structure, and
a data storage pattern connected to another side in the second direction of the semiconductor structure,
wherein the semiconductor structure includes a first portions overlapping with the word line in the first direction, having the other side in the second direction connected to the data storage pattern, and spaced apart in the first direction, and a second portion extending in the first direction, connecting the first portions, and positioned between the bit line and the first portions.
